(19) United States
(12) Patent Application Publication
(10) Pub. No.: US 2025/0224329 A1
(43) Pub. Date: Jul. 10, 2025

(54) SUBSTRATE EVALUATION METHOD AND SUBSTRATE PROCESSING APPARATUS

(71) Applicant: Tokyo Electron Limited, Tokyo (JP)

(72) Inventor: Yuji OTSUKI, Albany, NY (US)

(21) Appl. No.: 19/090,475

(22) Filed: Mar. 26, 2025

Related U.S. Application Data
(63) Continuation of application No. PCT/JP2023/033807, filed on Sep. 15, 2023.

(30) Foreign Application Priority Data
Sep. 28, 2022 (JP) 2022-155159

(51) Int. Cl. G01N 21/31; G01N 21/25; G01N 21/3563; G01N 21/84

(52) U.S. Cl. CPC G01N 21/3103; G01N 21/255; G01N 21/3563; G01N 21/8422; G01N 2021/3568; G01N 2021/8433

(57) ABSTRACT

A substrate evaluation method includes: a measurement operation of measuring an absorbance spectrum in a wavenumber range including a peak of at least one of a LO (Longitudinal Optical) phonon or a TO (Transverse Optical) phonon by analyzing a substrate having an anisotropic structure formed thereon with an infrared spectroscopy analysis; and a derivation operation of deriving evaluation information about the anisotropic structure from the measured absorbance spectrum.

### CROSS-REFERENCE TO RELATED APPLICATIONS

This application is a bypass continuation application of international application No. PCT/JP2023/033807 having an international filing date of Sep. 15, 2023 and designating the United States, the international application being based upon and claiming the benefit of priority from Japanese Patent Application No. 2022-155159, filed on Sep. 28, 2022, the entire contents of which are incorporated herein by reference.

### TECHNICAL FIELD

The present disclosure relates to a substrate evaluation method and a substrate processing apparatus.

### BACKGROUND

Patent Document 1 discloses a technique for evaluating an insulating thin film formed on a wafer from a wavenumber of a LO (Longitudinal Optical) phonon, a half-width of a spectral peak, and an absorption area which are observed by applying infrared spectroscopy to the insulating thin film.

### PRIOR ART DOCUMENT

### Patent Document

Patent Document 1: Japanese Laid-Open Patent Publication No. 2004-055955

### SUMMARY

According to one embodiment of the present disclosure, a substrate evaluation method includes: a measurement operation of measuring an absorbance spectrum in a wavenumber range including a peak of at least one of a LO (Longitudinal Optical) phonon or a TO (Transverse Optical) phonon by analyzing a substrate having an anisotropic structure formed thereon with an infrared spectroscopy analysis; and a derivation operation of deriving evaluation information about the anisotropic structure from the measured absorbance spectrum.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view showing an example of a schematic configuration of a film forming apparatus according to a first embodiment.

FIG. 2 is a diagram showing a state in which a substrate is raised from a stage of the film forming apparatus according to the first embodiment.

FIG. 3 is a schematic diagram showing another example of the film forming apparatus according to the first embodiment.

FIG. 4 is a diagram showing an example of a substrate according to the first embodiment.

FIG. 5A is a diagram for explaining an influence of a phonon on a flat substrate.

FIG. 5B is a diagram for explaining an influence of the phonon on the flat substrate.

FIG. 5C is a diagram for explaining an influence of the phonon on the flat substrate.

FIG. 6A is a diagram for explaining an influence of a phonon on a substrate in which a trench is formed.

FIG. 6B is a diagram for explaining an influence of the phonon on the substrate in which the trench is formed.

FIG. 7A is a diagram showing an example of an incident angle of measurement light with respect to the substrate.

FIG. 7B is a diagram showing an example of an absorbance spectrum.

FIG. 8A is a diagram showing an example of an absorbance spectrum according to the first embodiment.

FIG. 8B is a diagram showing an example of the absorbance spectrum according to the first embodiment.

FIG. 9A is a diagram showing an example of a correlation according to the first embodiment.

FIG. 9B is a diagram showing an example of the correlation according to the first embodiment.

FIG. 10A is a diagram for explaining an example of a substrate processing flow including a process of a substrate evaluation method according to the first embodiment.

FIG. 10B is a diagram for explaining an example of the substrate processing flow including the process of the substrate evaluation method according to the first embodiment.

FIG. 11 is a flowchart for explaining an example of the substrate processing flow according to the first embodiment.

FIG. 12 is a diagram for explaining a dependence of a substrate on polarized light.

FIG. 13A is a diagram for explaining an example of evaluation of a film quality by a substrate evaluation method according to a second embodiment.

FIG. 13B is a diagram for explaining an example of the evaluation of the film quality by the substrate evaluation method according to the second embodiment.

FIG. 14A is a diagram for explaining the separation of a TO phonon signal and a LO phonon signal according to the second embodiment.

FIG. 14B is a diagram for explaining the separation of a TO phonon signal and a LO phonon signal according to the second embodiment.

FIG. 15A is a diagram for explaining an example of the evaluation of the film quality by the substrate evaluation method according to the second embodiment.

FIG. 15B is a diagram for explaining an example of the evaluation of the film quality by the substrate evaluation method according to the second embodiment.

FIG. 16 is a diagram showing an example of an incident angle of measurement light on the substrate according to the second embodiment.

FIG. 17 is a flowchart for explaining an example of a substrate processing flow according to the second embodiment.

FIG. 18 is a schematic diagram showing a film forming apparatus according to another embodiment.

FIG. 19 is a diagram showing an example of a schematic configuration of a measurer according to an embodiment.

FIG. 20 is a diagram showing an example of a schematic configuration of a measurer according to an embodiment.

### DETAILED DESCRIPTION

Hereinafter, embodiments of a substrate evaluation method and a substrate processing apparatus disclosed herein will be described in detail with reference to the accompanying drawings. Further, the substrate evaluation method and the substrate processing apparatus disclosed herein are not limited to the embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a semiconductor device manufacture, an anisotropic structure may be formed on a substrate such as a semiconductor wafer or the like. Examples of the anisotropic structure may include a trench (groove). In the semiconductor device manufacture, a substrate processing such as a film forming process of forming a film or an etching process of etching the film on a surface is performed on the substrate on which the anisotropic structure is formed. In the semiconductor device manufacture, with the the progress of miniaturization, it is important to accurately grasp a state of the anisotropic structure.

Therefore, a technique for detecting a state of an anisotropic structure formed on a substrate is required.

### First Embodiment

### [Configuration of Film Forming Apparatus]

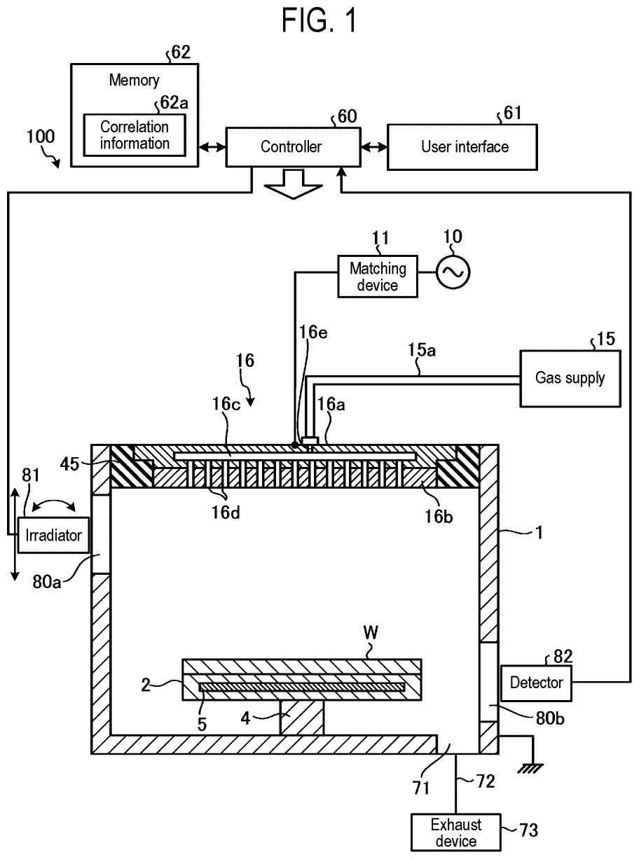

Next, a first embodiment will be described. First, an example of a substrate processing apparatus of the present disclosure will be described. In the following, a case in which the substrate processing apparatus of the present disclosure is a film forming apparatus 100, and film formation is performed as a substrate processing by the film forming apparatus 100 will be mainly described by way of example. FIG. 1 is a schematic cross-sectional view showing an example of a schematic configuration of the film forming apparatus 100 according to the first embodiment. In one embodiment, the film forming apparatus 100 is an apparatus which forms a film on a substrate W. The film forming apparatus 100 shown in FIG. 1 includes a chamber 1 which is hermetically sealed and electrically grounded. The chamber 1 has a cylindrical shape and is made of, for example, aluminum, nickel, or the like with an anodized coating formed on a surface thereof. A stage 2 is provided inside the chamber 1.

The stage 2 is made of a metal such as aluminum or nickel. The substrate W such as a semiconductor wafer is placed on an upper surface of the stage 2. The stage 2 horizontally supports the substrate W placed thereon. A lower surface of the stage 2 is electrically connected to a support 4 made of a conductive material. The stage 2 is supported by the support 4. The support 4 is supported by a bottom surface of the chamber 1. A lower end of the support 4 is electrically connected to the bottom surface of the chamber 1 and is grounded via the chamber 1. The lower end of the support 4 may be electrically connected to the bottom surface of the chamber 1 via a circuit configured to reduce an impedance between the stage 2 and a ground potential.

The stage 2 includes a built-in heater 5. The heater 5 may heat the substrate W placed on the stage 2 to a predetermined temperature. A flow path (not shown) for circulating coolant therethrough may be formed inside the stage 2. The coolant whose temperature is controlled by a chiller unit provided outside the chamber 1 may be supplied into the flow path to circulate therein. The stage 2 may control a temperature of the substrate W to a predetermined temperature by heating the substrate W with the heater 5 and cooling the substrate W with the coolant supplied from the chiller unit. The stage 2 may control the temperature of the substrate W only with the coolant supplied from the chiller unit instead of the heater 5.

An electrode may be embedded in the stage 2. By an electrostatic force generated by applying a DC voltage to the electrode, the stage 2 may attract the substrate W placed on the upper surface thereof.

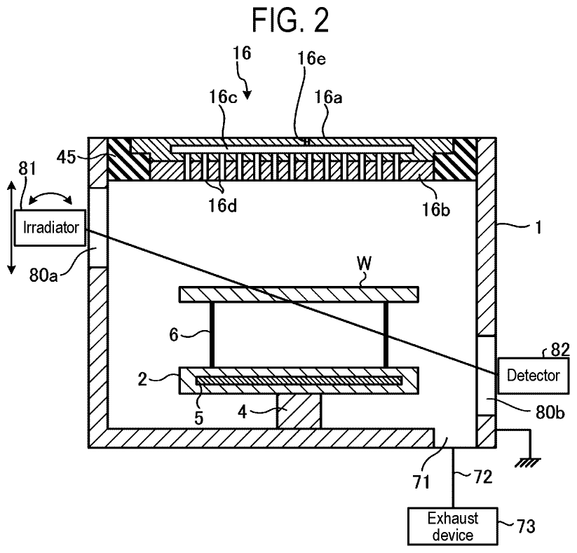

The stage 2 is provided with lifting pins 6 for raising and lowering the substrate W. In the film forming apparatus 100, when the substrate W is transferred or when infrared spectroscopy is performed on the substrate W, the lifting pins 6 protrude from the stage 2 to support the substrate W from the back surface of the substrate W by the lifting pins 6, and to raise the substrate W from the stage 2. FIG. 2 is a diagram showing a state in which the substrate W is raised from the stage 2 in the film forming apparatus 100 according to the first embodiment. The substrate W is transferred to the film forming apparatus 100. For example, a loading/unloading port (not shown) for loading and unloading the substrate W therethrough is provided in a sidewall of the chamber 1. A gate valve for opening and closing the loading/unloading port is provided at the loading/unloading port. When loading and unloading the substrate W, the gate valve remains opened. The substrate W is loaded into the chamber 1 from the loading/unloading port by a transfer mechanism (not shown) inside the transfer chamber. The film forming apparatus 100 receives the substrate W from the transfer mechanism by controlling a lifting mechanism (not shown) provided outside the chamber 1 to raise the lifting pins 6. After the transfer mechanism is withdrawn from the chamber 1, the film forming apparatus 100 controls the lifting mechanism to lower the lifting pins 6 to place the substrate W on the stage 2.

A shower head 16, which is formed in a substantially disk shape, is provided above the stage 2 on an inner surface of the chamber 1. The shower head 16 is supported above the stage 2 by an insulating member 45 such as ceramics or the like. Thus, the chamber 1 is electrically insulated from the shower head 16. The shower head 16 is made of a conductive metal such as nickel or the like.

The shower head 16 includes a top plate member 16a and a shower plate 16b. The top plate member 16a is provided so as to close an interior of the chamber 1 from above. The shower plate 16b is provided below the top plate member 16a so as to face the stage 2. A gas diffusion space 16c is formed in the top plate member 16a. The top plate member 16a and the shower plate 16b have a large number of gas ejection holes 16d formed in a dispersed manner and open toward the gas diffusion space 16c.

The top plate member 16a is formed with a gas introduction port 16e for introducing various gases into the gas diffusion space 16c therethrough. The gas introduction port 16e is connected to a gas supply path 15a. The gas supply path 15a is connected to a gas supply 15.

The gas supply 15 includes gas supply lines connected to gas sources of various gases used in film formation. The gas supply lines are branched appropriately according to the film forming process. Each of the gas supply lines is provided with control devices for controlling a flow rate of a gas, for example, a valve such as an opening/closing valve or the like, and a flow rate controller such as a mass flow controller or the like. The gas supply 15 may control the flow rates of various gases by controlling the control devices, such as the opening/closing valve and the flow rate controller, which are provided in each gas supply line.

The gas supply 15 supplies various gases used in film formation to the gas supply path 15a. For example, the gas supply 15 supplies a raw material gas for film formation to the gas supply path 15a. Further, the gas supply 15 supplies a purge gas and a reaction gas that reacts with the raw material gas to the gas supply path 15a. The gas supplied to the gas supply path 15a diffuses in the gas diffusion space 16c and is discharged from each gas discharge hole 16d.

A space surrounded by a lower surface of the shower plate 16b and the upper surface of the stage 2 forms a processing space in which a film forming process is performed. The shower plate 16b is paired with the stage 2 to function as an electrode plate for forming capacitively coupled plasma (CCP) in the processing space. The shower head 16 is connected to a radio-frequency power supply 10 via a matching device 11. Radio-frequency power (RF power) is applied from the radio-frequency power supply 10 to the gas supplied to the processing space via the shower head 16, thereby forming plasma in the processing space. The radio-frequency power supply 10 may be connected to the stage 2 instead of being connected to the shower head 16. The shower head 16 may be grounded. In this embodiment, parts which implement the film formation, such as the shower head 16, the gas supply 15, and the radio-frequency power supply 10, correspond to a substrate processor which performs the substrate processing on the substrate W. In this embodiment, the substrate processor performs the film forming process as the substrate processing on the substrate W.

An exhaust port 71 is formed at the bottom portion of the chamber 1. An exhaust device 73 is connected to the exhaust port 71 via an exhaust pipe 72. The exhaust device 73 includes a vacuum pump and a pressure regulation valve. The exhaust device 73 may reduce and regulate an internal pressure of the chamber 1 to a predetermined vacuum level by operating the vacuum pump and the pressure regulation valve.

The film forming apparatus 100 according to the present embodiment analyzes the substrate W inside the chamber 1 using infrared spectroscopy (IR) to derive evaluation information about a structure formed on the substrate W. The infrared spectroscopy includes a method of irradiating the substrate W with infrared light and measuring light (transmitted light) transmitted through the substrate W (transmission method), and a method of measuring light (reflected light) reflected from the substrate W (reflection method). The film forming apparatus 100 shown in FIG. 1 shows an example of a configuration in which the transmitted light transmitted through the substrate W is measured. The chamber 1 includes windows 80a and 80b provided on sidewalls facing each other across the stage 2. The window 80a is provided at a relatively high position on the sidewall. The window 80b is provided at a relatively low position on the sidewall. The windows 80a and 80b are sealed with a member such as quartz that is transparent to the infrared light. An irradiator 81 configured to irradiate the infrared light is provided outside the window 80a. A detector 82 capable of detecting the infrared light is provided outside the window 80b.

When performing the infrared spectroscopy analysis using the transmission method, in the film forming apparatus 100, as shown in FIG. 2, the lifting pins 6 protrude from the stage 2 to raise the substrate W from the stage 2. Positions of the window 80a and the irradiator 81 are adjusted so that the infrared light irradiated from the irradiator 81 is irradiated via the window 80a onto the upper surface of the raised substrate W. Positions of the window 80b and the detector 82 are adjusted so that the transmitted light that has passed through the raised substrate W is incident on the detector 82 via the window 80b.

The irradiator 81 is disposed so that the irradiated infrared light passes through the window 80a and reaches a predetermined area near the center of the raised substrate W. The detector 82 is disposed so that the transmitted light that has passed through the predetermined area of the substrate W is incident on the detector 82 via the window 80b.

The film forming apparatus 100 according to the present embodiment uses the infrared spectroscopy to determine absorbance for each wavenumber of the transmitted light that has passed through the substrate W, thereby deriving evaluation information about the structure formed on the substrate W. Specifically, the film forming apparatus 100 uses Fourier transform infrared spectroscopy to determine the absorbance for each wavenumber of the transmitted light that has passed through the substrate W, thereby deriving the evaluation information about the trench formed in the substrate W.

The irradiator 81 incorporates a light source for emitting the infrared light, and optical elements such as a mirror and a lens, and is capable of irradiating interfered infrared light. For example, the irradiator 81 splits an intermediate portion of the optical path of the infrared light generated by the light source, which extends to a point where the infrared light is emitted to the outside, into two optical paths by a half mirror or the like. In the irradiator 81, an optical path length of one of the two optical paths varies relative to an optical path length of the other to change an optical path difference and cause interference therebetween. Thus, infrared light of various interference waves having various optical path differences is irradiated. In addition, the irradiator 81 is capable of controlling a polarization of the infrared light to be irradiated by providing an optical element such as a polarizer or the like in the optical path. The irradiator 81 may be provided with a plurality of light sources, and may control the infrared light of each light source by an optical element, thereby irradiating the infrared light of various interference waves having various optical path differences.

The detector 82 detects a signal intensity of transmitted light of infrared light of various interference waves that have been transmitted through the substrate W. In this embodiment, parts which perform the measurement based on the infrared spectroscopy, such as the irradiator 81, the detector 82 and the like, correspond to a measurer of the present disclosure.

An overall operation of the film forming apparatus 100 configured as above is controlled by a controller 60. A user interface 61 and a memory 62 are connected to the controller 60.

The user interface 61 is constituted with an operation device such as a keyboard through which a process manager inputs commands to manage the film forming apparatus 100, and a display device such as a display which visually displays an operating state of the film forming apparatus 100. The user interface 61 accepts various operations. For example, the user interface 61 accepts a predetermined operation to instruct the start of plasma processing.

The memory 62 stores programs (software) for implementing various processes executed in the film forming apparatus 100 under the control of the controller 60, and pieces of data such as processing conditions and process parameters. For example, the memory 62 stores correlation information 62a. Further, the programs and data may be stored in a non-transitory computer-readable recording medium (for example, a hard disk, a CD, a flexible disk, a semiconductor memory, or the like). Alternatively, the programs and data may be transmitted from another device at any time via, for example, a dedicated line and may be used in an online environment.

The correlation information 62a is data indicating a correlation between the absorbance spectrum and the anisotropic structure formed on the substrate W. The correlation information 62a will be described in detail later.

The controller 60 is, for example, a computer including a processor, a memory, and the like. The controller 60 reads out programs and data from the memory 62 based on the instructions from the user interface 61, or the like, and controls individual constituent elements of the film forming apparatus 100 to perform the substrate processing, which will be described later.

The controller 60 is connected to the irradiator 81 and the detector 82 via an interface (not shown) for inputting and outputting data, and is configured to input and output various pieces of information. The controller 60 controls the irradiator 81 and the detector 82. For example, the irradiator 81 irradiates various interference waves having various optical path differences based on control information from the controller 60. In addition, data about a signal intensity of the infrared light detected by the detector 82 is input to the controller 60.

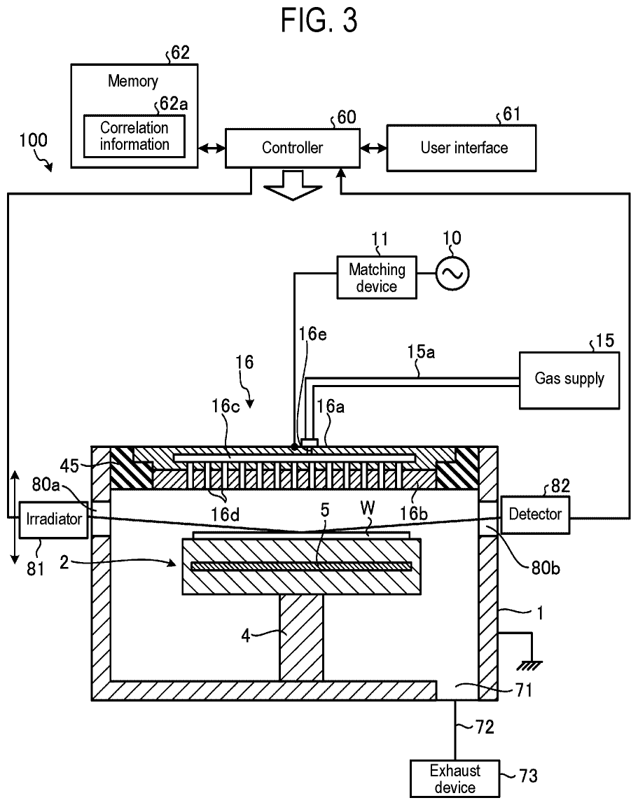

In FIGS. 1 and 2, an example has been described in which the film forming apparatus 100 is configured to measure the transmitted light transmitted through the substrate W so that the infrared spectroscopy analysis using the transmission method may be performed. However, the film forming apparatus 100 may be configured to implement the infrared spectroscopy analysis using the reflection method. FIG. 3 is a schematic diagram showing another example of the film forming apparatus 100 according to the first embodiment. FIG. 3 shows an example in which the film forming apparatus 100 is configured to measure the reflected light reflected from the substrate W.

In the film forming apparatus 100 shown in FIG. 3, windows 80a and 80b are provided on the sidewall of the chamber 1 at positions facing each other across the stage 2. An irradiator 81 which irradiates infrared light is provided outside the window 80a. A detector 82 configured to detect the infrared light is provided outside the window 80b. Positions of the window 80a and the irradiator 81 are adjusted so that the infrared light irradiated from the irradiator 81 is irradiated onto the substrate W via the window 80a. Positions of the window 80b and the detector 82 are adjusted so that the infrared light reflected by the substrate W is incident on the detector 82 via the window 80b. A loading/unloading port (not shown) for loading and unloading the substrate W therethrough is provided at a position different from the positions of the windows 80a and 80b on the sidewall of the chamber 1. A gate valve for opening and closing the loading/unloading port is provided at the loading/unloading port.

The irradiator 81 is disposed so that the irradiated infrared light reaches a predetermined area near the center of the substrate W via the window 80a. The detector 82 is disposed so that the infrared light reflected from the predetermined area of the substrate W is incident onto the detector 82 via the window 80b. In this manner, the film forming apparatus 100 shown in FIG. 3 is capable of implementing the infrared spectroscopy analysis using the reflection method.

The film forming apparatus 100 according to the first embodiment may be configured to change an incident angle and irradiation position of the light incident on the substrate W from the irradiator 81. For example, in FIGS. 1 and 3, the irradiator 81 is configured to be movable in the vertical direction and rotatable by a driving mechanism (not shown), so that the incident angle and irradiation position of the light incident on the substrate W from the irradiator 81 may be changed.

Next, a flow of performing a film forming process as a substrate processing on the substrate W by the film forming apparatus 100 according to the first embodiment will be briefly described. The substrate W is placed on the stage 2 by a transfer mechanism such as a transfer arm (not shown). A trench is formed as an anisotropic structure in the substrate W. When performing the film forming process on the substrate W, the film forming apparatus 100 reduces the internal pressure of the chamber 1 by the exhaust device 73. The film forming apparatus 100 supplies various gases used in film formation from the gas supply 15 and introduces processing gases into the chamber 1 from the shower head 16. Subsequently, the film forming apparatus 100 supplies radio-frequency power from the radio-frequency power supply 10 to generate plasma in the processing space, and performs the film formation on the substrate W.

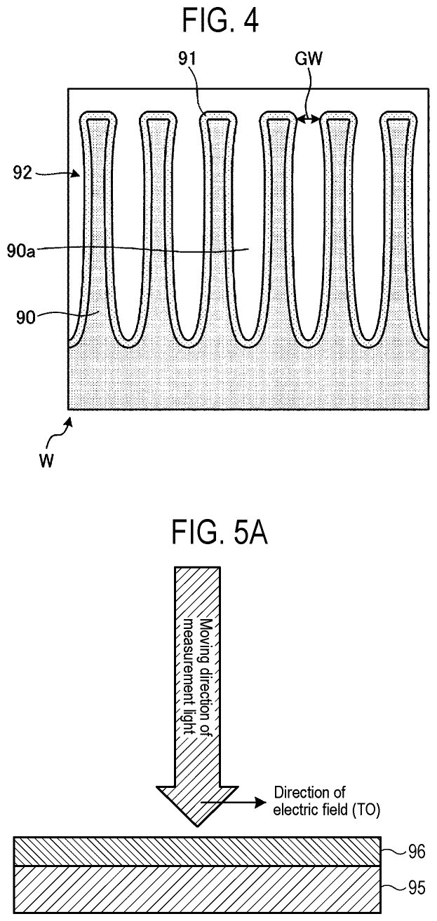

FIG. 4 is a diagram showing an example of the substrate W according to the first embodiment. The anisotropic structure is formed on the substrate W. For example, the substrate W has a pattern 90 formed with a plurality of trenches 92 as the anisotropic structure. FIG. 4 shows a cross section of a recess 90a formed by each trench 92. FIG. 4 shows a schematic diagram of a state in which a film 91 is formed on the pattern 90 having the trenches 92 by plasma ALD. For example, in FIG. 4, the film 91 is formed in the trenches 92 formed on the substrate W.

In the semiconductor device manufacture, with the progress of miniaturization, it is important to accurately grasp a state of the anisotropic structure formed on the substrate W. For example, a state of the trench 92 formed in the substrate W needs to be accurately grasped.

In the related art, infrared spectroscopy such as Fourier transform infrared spectroscopy (FT-IR) has been used as a technique for analyzing the state of the substrate W. In the FT-IR analysis, infrared light is irradiated onto the substrate W, and the infrared light transmitted through or reflected by the substrate W is detected to obtain an absorbance spectrum indicating an absorbance of the infrared light for each wavenumber.

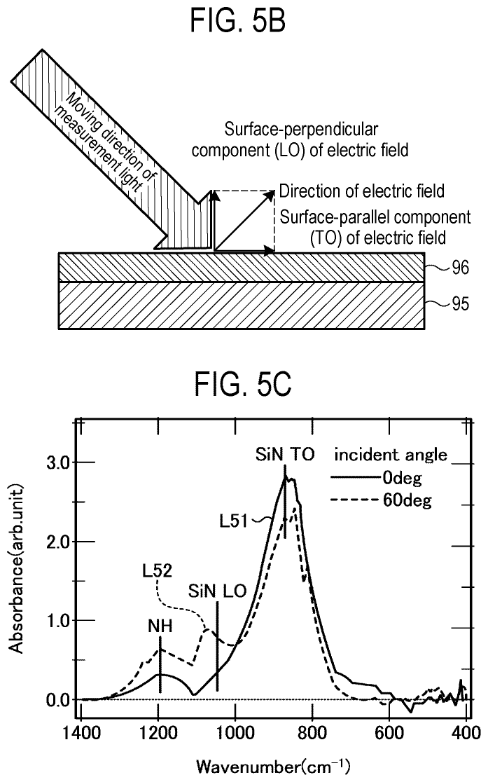

Hereinafter, the influence of a phonon in the FT-IR analysis will be described. FIGS. 5A and 5B are diagrams for explaining the influence of the phonon on a flat substrate. FIGS. 5A and 5B show a case in which the infrared light is incident as measurement light on a flat silicon substrate 95. A film 96 is formed on a surface of the silicon substrate 95. The film 96 contains an infrared-active material. In the FT-IR analysis, the infrared light transmitted through or reflected by the silicon substrate 95 is detected to obtain the absorbance spectrum indicating the absorbance of the infrared light for each wavenumber. FIG. 5A shows a case in which the infrared light is perpendicularly incident as the measurement light on the flat silicon substrate 95. When the measurement light is perpendicularly incident as shown in FIG. 5A, an electric field of the measurement light is parallel to the surface of the silicon substrate 95. In this case, a TO (Transverse Optical) phonon, which is a surface parallel component of the film 96 on the surface of the silicon substrate 95, is observed. FIG. 5B shows a case in which the infrared light is obliquely incident as the measurement light on the flat silicon substrate 95. When the measurement light is obliquely incident as shown in FIG. 5B, the electric field of the measurement light is oblique to the silicon substrate 95. In this case, the TO phonon, which is the surface parallel component of the film 96 on the surface of the silicon substrate 95, is observed due to the surface parallel component of the electric field of the measurement light with respect to the silicon substrate 95. In addition, a LO (Longitudinal Optical) phonon, which is a surface perpendicular component of the film 96 on the surface of the silicon substrate 95, is observed due to the surface perpendicular component of the electric field of the measurement light with respect to the silicon substrate 95.

FIG. 5C is a diagram showing an example of the absorbance spectrum in the flat silicon substrate 95. FIG. 5C shows an example of results of performing the FT-IR analysis on the flat silicon substrate 95 on which the film 96 is formed to obtain the absorbance spectrum. Line L51 indicates the case in which the infrared light is perpendicularly incident on the flat silicon substrate 95 as the measurement light at an incident angle of 0 degrees. Line L52 indicates the case in which the infrared light is obliquely incident on the flat silicon substrate 95 as the measurement light at an incident angle of 60 degrees. In addition, FIG. 5C shows positions of wavenumbers which are peaks of the LO phonon and TO phonon of SiN. When the measurement light is perpendicularly incident on the flat silicon substrate 95 as indicated by line L51, the TO phonon of SiN is observed. On the other hand, when the measurement light is obliquely incident on the flat silicon substrate 95 as indicated by line L52, the TO phonon and LO phonon of SiN are observed.

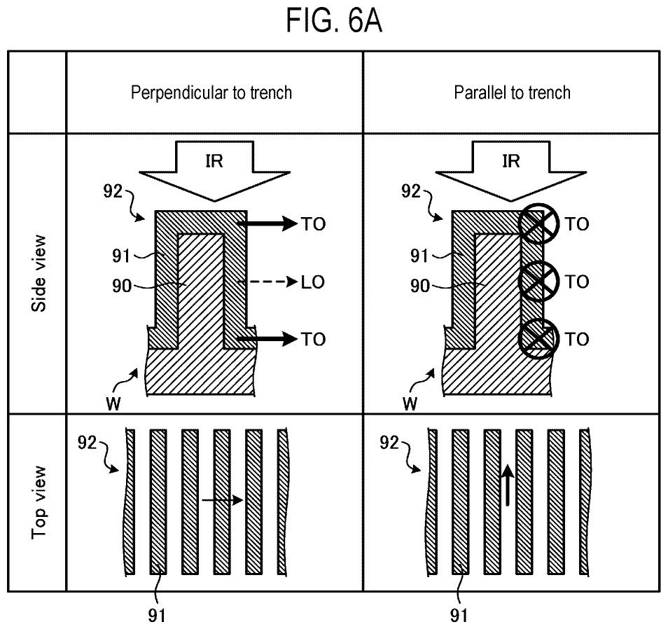

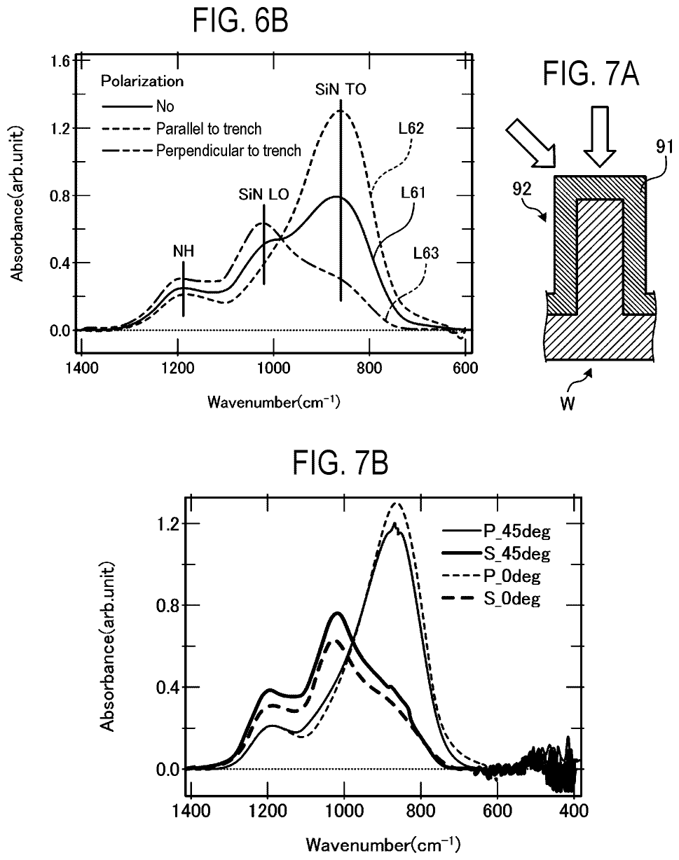

FIGS. 6A and 6B are diagrams for explaining an influence of the phonon on the substrate W in which the trench 92 is formed. In the substrate W, the trench 92 is formed as the pattern 90, and the film 91 is formed in the trench 92. In FIG. 6A, a cross section of the trench 92 is shown as a “Side view” and an upper surface of the trench 92 is shown as a “Top view”. As shown in the “Top view”, a plurality of trenches 92 are formed step-by-step in a vertical direction. FIG. 6A shows the case in which the infrared light is perpendicularly incident on the substrate W as the measurement light. In FIG. 6A, a case in which the polarization of the measurement light is perpendicular to the trench 92 (Perpendicular to trench) and a case in which the polarization of the measurement light is parallel to the trench 92 (Parallel to trench) are shown. The polarization of the measurement light is controlled by, for example, providing an optical element such as a polarizer in a path of the measurement light. In the “Top view” column of “Perpendicular to trench”, the polarization of the measurement light is indicated by an arrow as being perpendicular to the trench 92. In the “Top view” column of “Parallel to trench,” the polarization of the measurement light is indicated by an arrow as being parallel to the trench 92. In the substrate W having the trench 92 formed therein, when the polarization of the measurement light is perpendicular to the trench 92 (Perpendicular to trench), the TO phonon and LO phonon of the film 91 on the surface of the substrate W are observed. Further, in the substrate W having the trench 92 formed therein, when the polarization of the measurement light is parallel to the trench 92 (Parallel to trench), the TO phonon of the film 91 on the surface of the substrate W is observed.

FIG. 6B shows an example of results of obtaining the absorbance spectrum by performing the FT-IR analysis on the substrate W in which the trench 92 is formed and the film 91 is formed in the trench 92. The absorbance spectrum shows the absorbance of the infrared light for each wavenumber. The incident angle is 0 degrees, that is, the light is perpendicularly incident on the surface. Line L61 indicates an absorbance spectrum in a case of unpolarized light in which the polarization is not controlled (indicated by “No”. Line L62 indicates an absorbance spectrum in the case of the polarization of the measurement light being parallel to the trench 92 (indicated by “Parallel to trench”). Line L63 indicates an absorbance spectrum in the case of the polarization of the measurement light being perpendicular to the trench 92 (indicated by “Perpendicular to trench”). In this way, a shape of the absorbance spectrum is changed depending on the polarization of the measurement light. In the case of the unpolarized light in which the polarization is not controlled, the measurement light has both perpendicular and parallel polarization components with respect to the trench 92. Therefore, in the FT-IR analysis using the unpolarized measurement light, both the TO phonon and the LO phonon are observed.

The incident angle of the measurement light on the substrate W in the FT-IR analysis may be any angle. For example, the measurement light may be perpendicularly incident on the substrate W, and the infrared light transmitted through or reflected by the substrate W may be detected to obtain the absorbance spectrum. Alternatively, the measurement light may be obliquely incident on the substrate W, and the infrared light transmitted through or reflected by the substrate W may be detected to obtain the absorbance spectrum. FIG. 7A is a diagram showing an example of the incident angle of the measurement light on the substrate W. FIG. 7A shows a case in which the measurement light is perpendicularly incident on the substrate W at an incident angle of 0 degrees and a case in which the measurement light is obliquely incident on the substrate W at an incident angle of 45 degrees. FIG. 7B is a diagram showing an example of the absorbance spectrum. FIG. 7B shows absorbance spectra when the measurement light is perpendicularly incident on the substrate W at an incident angle of 0 degrees (0 deg) and when the measurement light is obliquely incident on the substrate W at an incident angle of 45 degrees (45 deg). (P-polarized) measurement light polarized parallel to the trench, and (S-polarized) measurement light polarized perpendicular to the trench are incident separately. The polarization of the measurement light is controlled by providing an optical element such as a polarizer in the path of the measurement light. “P_45 deg” indicates the absorbance spectrum when the P-polarized measurement light polarized parallel to the trench is obliquely incident at an incident angle of 45 degrees. “S_45 deg” indicates the absorbance spectrum when the S-polarized measurement light polarized perpendicular to the trench is obliquely incident at an incident angle of 45 degrees. “P_0 deg” indicates the absorbance spectrum when the P-polarized measurement light polarized parallel to the trench is perpendicularly incident at an incident angle of 0 degrees. “S_0 deg” indicates the absorbance spectrum when the S-polarized measurement light polarized perpendicular to the trench is perpendicularly incident at an incident angle of 0 degrees. Peak intensities differ between the oblique incidence at the incident angle of 45 degrees and the perpendicular incidence at the incident angle of 0 degrees, but the absorbance spectra have similar shapes. Therefore, the incident angle of the measurement light on the substrate W during the FT-IR analysis may be any angle.

There is a correlation between the TO phonon or the LO phonon observed in the absorbance spectrum obtained by performing the infrared spectroscopy analysis on the substrate W on which the anisotropic structure is formed, and the state of the anisotropic structure.

The correlation between the anisotropic structure formed on the substrate W and the TO phonon and LO phonon observed in the absorbance spectrum will be described. In this embodiment, the anisotropic structure is the trench 92.

First, the results of the FT-IR analysis performed on the substrates W by changing the opening width of the trench 92 will be described. In this embodiment, for example, as shown in FIG. 4, a width GW of the narrowest portion near an upper portion of the trench 92 is set as the opening width of the trench 92. In the following analysis, the absorbance spectrum of the substrate W is measured before and after the infrared-active material is deposited on the substrate W. First, the FT-IR analysis is performed on the substrate W with the trench 92 formed thereon to measure the absorbance spectrum. Subsequently, the infrared-active material is deposited on the substrate W. Examples of the infrared-active material may include SiN, SiO, SiC, AlO, HfO, ZrO and the like. Subsequently, the FT-IR analysis is performed on the substrate W with the infrared-active material deposited thereon to measure the absorbance spectrum. Thereafter, the absorbance spectrum is calculated from an intensity spectrum measured on the substrate W before the infrared-active material is deposited and an intensity spectrum measured on the substrate W after the infrared-active material is deposited. Hereafter, for example, as shown in FIG. 4, a base film is formed on the substrate W having the trench 92 formed therein, the opening width of the trench 92 is sequentially changed by changing a thickness of the pattern 90. In this way, the absorbance spectra are calculated. SiN as the infrared-active material is deposited on the substrate W by plasma ALD. For example, the film 91 is formed in the trench 92 as shown in FIG. 4. A film thickness of the film 91 is in a range of 0.1 nm to 10,000 nm, specifically in a range of 0.5 nm to 150 nm, and more specifically in a range of 1 nm to 15 nm.

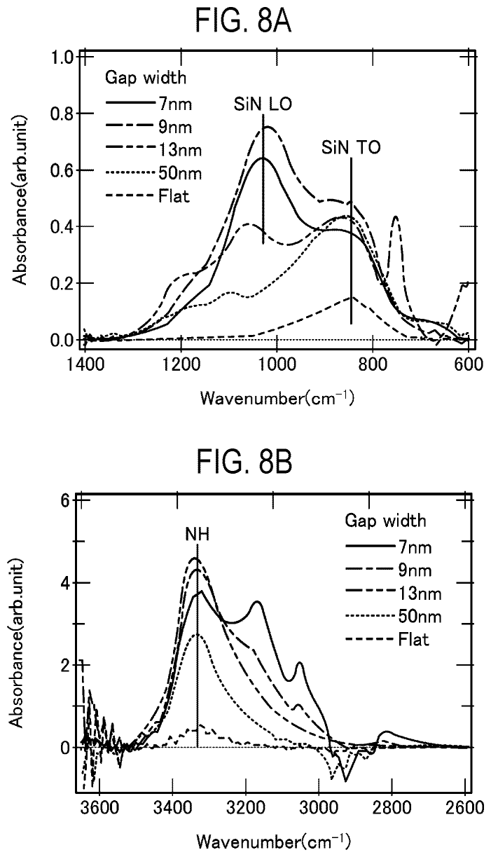

FIGS. 8A and 8B are diagrams showing an example of the absorbance spectrum according to the first embodiment. FIGS. 8A and 8B show examples of the absorbance spectrum obtained by performing the above-described analysis on the substrate W when the opening width (gap width) of the trench 92 is set to 7 nm, 9 nm, 13 nm, and 50 nm. Further, FIGS. 8A and 8B show an example of an absorbance spectrum obtained by performing the above-described analysis on the flat silicon substrate 95 (as indicated by “Flat”). In FIG. 8A, the absorbance spectrum in a wavenumber range of 600 to 1,400 cm⁻¹ is shown. In FIG. 8B, the absorbance spectrum in a wavenumber range of 2,600 to 3,600 cm⁻¹ is shown. The absorbance spectrum shows ae change in absorbance of the infrared light with respect to the film 91, which is obtained by analyzing the intensity spectrum of the substrate W before and after the film formation. That is, the absorbance spectrum mainly includes information about the film 91. In FIG. 8A, positions of wavenumbers at which the LO phonon and TO phonon of SiN have peaks. In FIG. 8B, positions of wavenumbers at which NH in the SiN film and the base film of the substrate W has a peak.

As shown in FIGS. 8A and 8B, the absorbance spectrum is changed in the substrate W when the opening width of the trench 92 is set to 7 nm, 9 nm, 13 nm, and 50 nm, respectively. In particular, the peak intensity of the LO phonon of SiN is changed significantly. On the other hand, in the flat silicon substrate 95 (Flat), the peak intensity of the LO phonon of SiN is small.

The peak intensity of at least one of the LO phonon or the TO phonon of SiN is correlated with the opening width of the trench 92.

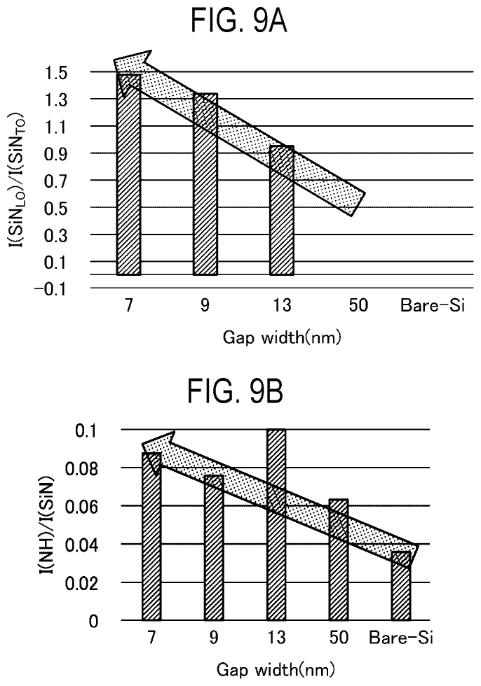

FIGS. 9A and 9B are diagrams showing an example of the correlation according to the first embodiment. FIG. 9A shows values of I(SiN_{LO})/I(SiN_{TO}) in the substrate W and the flat silicon substrate 95 (as indicated by “Bare-Si”) when the opening width of the trench 92 is set to 7 nm, 9 nm, 13 nm, and 50 nm. The values of I(SiN_{LO})/I(SiN_{TO}) are values obtained by dividing the peak intensity (I(SiN_{LO})) of the LO phonon of SiN in the absorbance spectrum by the peak intensity (I(SiN_{TO})) of the TO phonon of SiN. As shown in FIG. 9A, the value of I(SiN_{LO})/I(SiN_{TO}) increases as the opening width of the trench 92 becomes narrower. There is a correlation between the value of I(SiN_{LO})/I(SiN_{TO}) and the opening width of the trench 92.

FIG. 9B shows values of I(NH)/I(SiN_{TO}) in the substrate W and the flat silicon substrate 95 (Bare-Si) when the opening width of the trench 92 is set to 7 nm, 9 nm, 13 nm, and 50 nm. The values of I(NH)/I(SiN_{TO}) are values obtained by dividing the peak intensity (I(NH)) of NH in the absorbance spectrum by the peak intensity (I(SiN_{TO})) of the TO phonon of SiN. As shown in FIG. 9B, the value of I(NH)/I(SiN_{TO}) tends to increase as the opening width of the trench 92 becomes narrower. There is a correlation between the value of I(NH)/I(SiN_{TO}) and the opening width of the trench 92. In FIG. 9B, the value of (NH)/I(SiN_{TO}) is large when the opening width of the trench 92 is 13 nm. It is considered that this is because NH is contained in the base film formed to change the opening width of the trench 92.

The reason why the correlations shown in FIGS. 9A and 9B occur is considered as follows. When the opening width of the trench 92 is narrowed, a distance between side surfaces of the trenches 92 facing each other is narrowed, and a vibration interaction occurs between the SiN films formed on the side surfaces, causing the SiN films to vibrate in synchronism with each other.

Therefore, in the substrate evaluation method according to the first embodiment, the opening width of the trench 92 formed in the substrate W is derived as follows.

First, in the substrate evaluation method according to the first embodiment, a plurality of substrates W on which trenches 92 having different opening widths are formed are prepared. A base film may be formed on one substrate W on which the trench 92 is formed to sequentially change the opening width of the trench 92. In the substrate evaluation method according to the first embodiment, the FT-IR analysis is performed before and after forming a film with the infrared-active material (for example, SiN) on each substrate W to measure the intensity spectra of the substrate W before and after such a film formation. Then, in the substrate evaluation method according to the first embodiment, an absorbance spectrum is calculated from the intensity spectra of the substrates W before and after the film formation for each substrate W having different opening widths of the trenches 92. Thereafter, in the substrate evaluation method according to the first embodiment, the peak intensity of at least one of the LO phonon or the TO phonon of SiN is observed from the absorbance spectra of the substrates W having different opening widths of the trenches 92, and correlation information 62a indicating the correlation with the opening width of the trench 92 is obtained. For example, in the substrate evaluation method according to the first embodiment, the correlation information 62a is obtained between the value (I(SiN_{LO})/I(SiN_{TO})) obtained by dividing the peak intensity of the LO phonon of SiN in the absorbance spectrum by the peak intensity of the TO phonon of SiN, and the opening width of the trench 92. Alternatively, in the substrate evaluation method according to the first embodiment, the correlation information 62a is obtained between the value (I(NH)/I(SiN_{TO})) obtained by dividing the peak intensity of NH in the absorbance spectrum by the peak intensity of the TO phonon of SiN, and the opening width of the trench 92. The film forming apparatus 100 according to the first embodiment stores the correlation information 62a in the memory 62.

The film forming apparatus 100 according to the first embodiment forms a film on the substrate W having the trench 92 formed therein, and detects the state of the trench 92 of the substrate W after the film formation on an in-line basis. Specifically, the substrate W is transferred to the film forming apparatus 100 and is placed on the stage 2. The film forming apparatus 100 measures the absorbance spectrum of the substrate W. Thereafter, the film forming apparatus 100 performs the film forming process using the infrared active material (for example, SiN) on the substrate W. The film forming apparatus 100 measures the absorbance spectrum of the substrate W after the film forming process.

The film forming apparatus 100 according to the first embodiment derives the evaluation information about the trench 92 from the intensity spectrum before the film forming process and the intensity spectrum after the film forming process. For example, the controller 60 calculates the absorbance spectrum from the intensity spectrum before the film forming process and the intensity spectrum after the film forming process. The controller 60 derives the opening width of the trench 92 of the substrate W from the calculated absorbance spectrum based on the correlation information 62a stored in the memory 62. For example, the controller 60 obtains the value of I(NH)/I(SiN_{TO}) or the value of I(NH)/I(SiN_{TO}) from the absorbance spectrum. The controller 60 derives the opening width of the trench 92 of the substrate W from the value of I(NH)/I(SiN_{TO}) or the value of I(NH)/I(SiN_{TO}) based on the correlation information 62a stored in the memory 62.

In this way, the film forming apparatus 100 according to the first embodiment may derive the opening width of the trench 92 formed in the substrate W. Further, since the film forming apparatus 100 according to the first embodiment may detect the opening width of the trench 92 on an in-line basis, it may also perform feedback control on the film forming process according to the detected opening width. For example, when the detected opening width does not satisfy a specified range, the film forming apparatus 100 may control the opening width of the trench 92 to fall within the specified range by performing the film forming process of forming the film 91 again.

In the first embodiment, the example has been described in which the substrate processing is the film forming process, the absorbance spectrum is calculated from the intensity spectrum of the substrate W before and after the film formation, and the opening width of the trench 92 is detected from the absorbance spectrum. However, the present disclosure is not limited thereto. The substrate processing may be any process relating to a semiconductor manufacturing process of manufacturing a semiconductor device, such as an etching process, a modification process or the like. For example, intensity spectra of the substrate W before and after the etching process are measured. Then, an absorbance spectrum may be calculated from the intensity spectra of the substrate W before and after the etching process, and the opening width of the trench 92 may be detected from the absorbance spectrum.

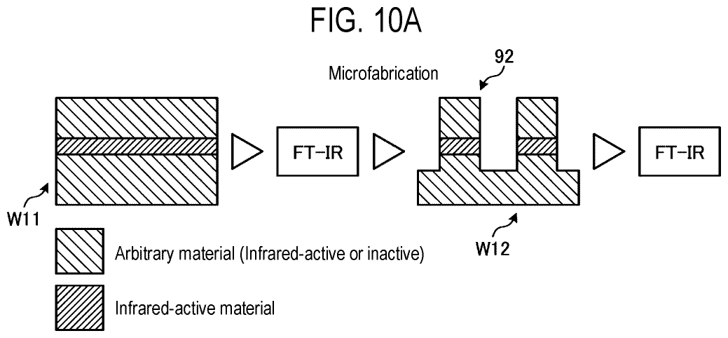

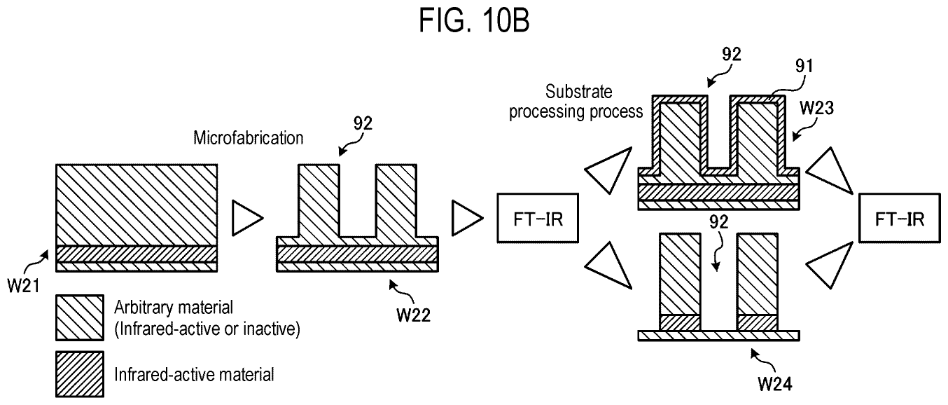

In the case in which a change occurs in the absorbance spectrum before and after microfabrication by the substrate processing, the FT-IR analysis may be performed before and after the microfabrication. FIG. 10A is a diagram for explaining an example of a flow of the substrate processing including the process of the substrate evaluation method according to the first embodiment. A substrate W11 is the substrate W before the substrate processing. In the substrate W11, a layer made of an infrared-active material is formed inside an arbitrary material. The arbitrary material may be an infrared-active material or an infrared-inactive material. In the substrate processing shown in FIG. 10A, the FT-IR analysis is performed on the substrate W11 to measure the intensity spectrum of the substrate W before the substrate processing. Subsequently, in the substrate processing shown in FIG. 10A, the microfabrication is performed on the substrate W11 by the substrate processing. For example, the etching process is performed on the substrate W11 to form the trench 92. A substrate W12 is the substrate W after the substrate processing. In the substrate W12, the trench 92 is formed downward of the layer made of the infrared-active material. Therefore, a change occurs in the intensity spectrum before and after the substrate processing. Then, in the substrate processing shown in FIG. 10A, the FT-IR analysis is performed on the substrate W12 to measure the intensity spectrum of the substrate W12 after the substrate processing. An absorbance spectrum is calculated from an intensity spectrum of the substrate W11 before the substrate processing and an intensity spectrum of the substrate W12 after the substrate processing, and the opening width of the trench 92 is derived from the absorbance spectrum. This makes it possible to detect the opening width of the trench 92 in a non-destructive manner.

In addition, when no change occurs in the absorbance spectrum before and after the microfabrication by the substrate processing, the following process may be performed. FIG. 10B is a diagram for explaining an example of the flow of the substrate processing including the process of the substrate evaluation method according to the first embodiment. A substrate W21 is the substrate W before the substrate processing. In the substrate W21, a layer made of an infrared-active material is formed inside an arbitrary material. The arbitrary material may be an infrared-active material or an infrared-inactive material. In this example, the arbitrary material is an infrared-inactive material. In the substrate processing shown in FIG. 10B, the microfabrication is performed on the substrate W21 by the substrate processing. For example, the etching process is performed on the substrate W21 to form the trench 92. A substrate W22 is the substrate W after the substrate processing. In the substrate W22, the trench 92 does not reach the layer made the infrared-active material. Therefore, no change occurs in a resonant absorption peak in the absorbance spectrum before and after the substrate processing. In the substrate processing shown in FIG. 10B, the FT-IR analysis is performed on the substrate W22 to measure the intensity spectrum of the substrate W22. In the substrate processing shown in FIG. 10B, the substrate W22 is processed so that the resonant absorption peak in the absorbance spectrum is changed. For example, the film 91 made of the infrared-active material is formed on the substrate W22, or the substrate W22 is etched until the trench 92 extends downward of the layer made of the infrared-active material. A substrate W23 is the substrate W in which the film 91 is formed on the trench 92. A substrate W24 is the substrate W in which the trench 92 is etched downward of the layer made of the infrared-active material. In the substrate processing shown in FIG. 10B, the FT-IR analysis is performed on the substrate W23 or W24 after the microfabrication to measure an intensity spectrum of the substrate W23 or W24 after the substrate processing. An absorbance spectrum is calculated from an intensity spectrum of the substrate W22 before the microfabrication and an intensity spectrum of the substrate W23 or W24 after the microfabrication, and the opening width of the trench 92 is detected from the absorbance spectrum. Therefore, the opening width of the trench 92 may be detected in a non-destructive manner.

Further, in the film forming apparatus 100, a change may occur in the absorbance spectrum measured from the substrate W due to a change over time in an amount of the measurement light irradiated from the irradiator 81. Even in such a case, the substrate evaluation method according to the first embodiment may extract information mainly from the film 91 by extracting the absorbance spectrum, and may stably derive the opening width of the trench 92. When the absorbance spectrum is stably measured and there is the correlation between the peak intensities of the LO phonon and the TO phonon of SiN in the absorbance spectrum and the opening width of the trench 92, the substrate evaluation method according to the first embodiment may derive the opening width of the trench 92 from the intensity spectrum of the substrate W before the film formation or the intensity spectrum of the substrate W after the film formation.

In the first embodiment, the example has been described in which the substrate processing is a film forming process, the absorbance spectrum is calculated from the intensity spectrum of the substrate W before and after the film formation, and the opening width of the trench 92 is derived from the absorbance spectrum. However, the present disclosure is not limited thereto. The substrate processing may be any process relating to the semiconductor manufacturing process of manufacturing a semiconductor device, such as an etching process, a resist coating process, a lithography process, an annealing process or the like. For example, the intensity spectrum of the substrate W before and after the etching process is measured, and the absorbance spectrum is calculated from the intensity spectrum of the substrate W before and after the etching process. Therefore, it is possible to derive the opening width of the trench 92 after the etching process.

In the first embodiment, the example has been described in which the anisotropic structure is the trench 92. However, the present disclosure is not limited thereto. The anisotropic structure may be any structure in which convex-concave portions or the like are formed in the substrate W in an anisotropic manner. The anisotropic structure may be a structure in which a smooth side surface is formed in at least one direction. A plurality of anisotropic structures having the same pattern may be formed side by side on the substrate W.

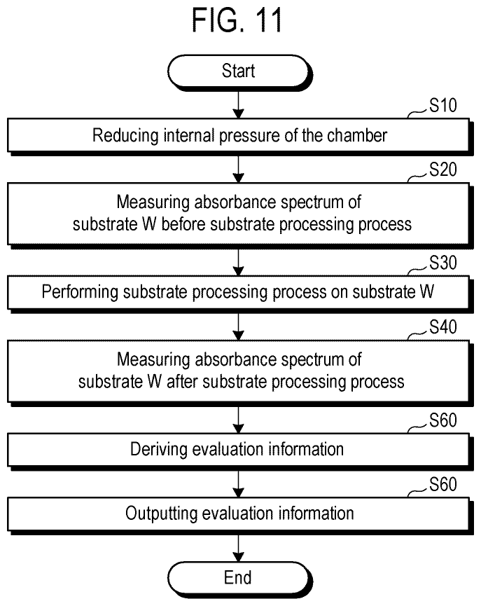

Next, a flow of the substrate processing including the process of the substrate evaluation method according to the first embodiment will be described. FIG. 11 is a flowchart for explaining an example of the flow of the substrate processing according to the first embodiment.

The substrate W having the trench 92 formed therein is placed on the stage 2 by a transfer mechanism such as a transfer arm (not shown). The film forming apparatus 100 reduces an internal pressure of the chamber 1 (Step S10). For example, the controller 60 controls the exhaust device 73 to reduce the internal pressure of the chamber 1.

Subsequently, the film forming apparatus 100 measures the absorbance spectrum of the substrate W before the substrate processing (Step S11). For example, the controller 60 controls the irradiator 81 to irradiate the substrate W with the infrared light from the irradiator 81, and detects the transmitted light that has passed through the substrate W or the reflected light that has been reflected by the substrate W with the detector 82. The controller 60 obtains the absorbance spectrum of the substrate W from the data detected by the detector 82.

Subsequently, the film forming apparatus 100 performs the substrate processing on the substrate W (Step S12). For example, the controller 60 controls the gas supply 15 and the radio-frequency power supply 10 to form the film 91 on the surface of the substrate W by the plasma ALD.

Subsequently, the film forming apparatus 100 measures the absorbance spectrum of the substrate W after the substrate processing (Step S13). For example, the controller 60 controls the irradiator 81 to irradiate the substrate W with the infrared light from the irradiator 81, and detects the transmitted light that has passed through the substrate W or the reflected light that has been reflected by the substrate W with the detector 82. The controller 60 obtains the absorbance spectrum of the substrate W from the data detected by the detector 82.

Thereafter, the film forming apparatus 100 derives the evaluation information about the trench 92 from the absorbance spectrum before the film forming process and the absorbance spectrum after the film forming process (Step S14). For example, the controller 60 calculates the absorbance spectrum from the intensity spectrum before the film forming process and the intensity spectrum after the film forming process. The controller 60 obtains the value of I(NH)/I(SiN_{TO}) or the value of I(NH)/I(SiN_{TO}) from the absorbance spectrum. The controller 60 derives the opening width of the trench 92 formed in the substrate W from the value of I(NH)/I(SiN_{TO}) or the value of I(NH)/I(SiN_{TO}) based on the correlation information 62a stored in the memory 62.

Subsequently, the film forming apparatus 100 outputs the derived evaluation information about the trench 92 (Step S15), and terminates the process. For example, the controller 60 outputs the derived opening width of the trench 92 to the user interface 61. Thus, a process manager may grasp the opening width of the trench 92 in real time. The controller 60 may output the evaluation information about the trench 92 to another apparatus. Further, the controller 60 may output the evaluation information about the trench 92 to the memory 62 or an external memory device.

As described above, the substrate evaluation method according to the first embodiment includes a measurement operation (Steps S11 and S13) and a derivation operation (Step S14). In the measurement operation, the substrate W on which the anisotropic structure is formed is analyzed by the infrared spectroscopy to measure the absorbance spectrum in the wavenumber range including the peak of at least one of the LO phonon or the TO phonon. In the derivation operation, the evaluation information about the anisotropic structure is derived from the measured absorbance spectrum. In this way, the substrate evaluation method according to the first embodiment may detect the state of the anisotropic structure formed on the substrate W.

The structure is the trench 92 formed in the substrate W. Thus, the substrate evaluation method according to the first embodiment may detect the state of the trench 92 formed in the substrate W.

Further, the film 91 made of the infrared-active material is formed on the trench 92. In the derivation operation, the peak intensities of the LO phonon and the TO phonon of the infrared-active material are obtained from the absorbance spectrum, and the opening width of the trench 92 is derived as the evaluation information from the peak intensities of the LO phonon and the TO phonon. Thus, the substrate evaluation method according to the first embodiment may detect the opening width of the trench 92 formed in the substrate W.

Further, the infrared-active material is SiN. Thus, the substrate evaluation method according to the first embodiment may detect the opening width of the trench 92 formed in the substrate W.

The substrate evaluation method according to the first embodiment further includes a substrate processing operation (Step S12) in which the substrate processing is performed on the substrate W. The measurement operation includes a pre-substrate-processing measurement operation (Step S11) and a post-substrate-processing measurement operation (Step S13). The pre-substrate-processing measurement operation performs the infrared spectroscopy analysis on the substrate W before the substrate processing in the substrate processing operation to measure the intensity spectrum before the substrate processing. The post-substrate-processing measurement operation performs the infrared spectroscopy analysis on the substrate W after the substrate processing in the substrate processing operation to measure the intensity spectrum after the substrate processing. The derivation operation derives the evaluation information about the anisotropic structure from the intensity spectrum before the substrate processing measured in the pre-substrate-processing measurement operation and the intensity spectrum after the substrate processing measured by the post-substrate-processing measurement operation. Thus, the substrate evaluation method according to the first embodiment may detect the state of the anisotropic structure after the substrate processing.

Further, the substrate processing operation includes forming the film made of the infrared-active material on the substrate W, or performing, as the substrate processing, an etching process or an ashing process of exposing the infrared-active material contained in the substrate W. The derivation operation calculates an absorbance spectrum from the intensity spectrum before the substrate processing and the intensity spectrum after the substrate processing, obtains the peak intensity of at least one of the LO phonon or the TO phonon of the infrared-active material from the absorbance spectrum, and derives the evaluation information about the anisotropic structure from the peak intensity of at least one of the LO phonon or the TO phonon. Thus, the substrate evaluation method according to the first embodiment may detect the state of the anisotropic structure after the substrate processing.

### Second Embodiment

Next, a second embodiment will be described. A configuration of the film forming apparatus 100 according to the second embodiment is similar to that of the film forming apparatus 100 according to the first embodiment shown in FIGS. 1 to 3, and therefore descriptions thereof will be omitted.

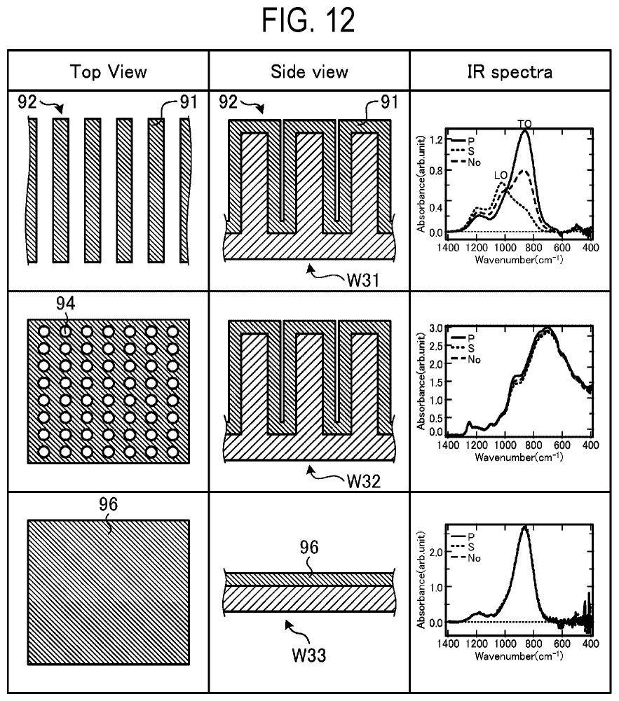

The substrate W has anisotropy with respect to the polarized measurement light incident on the substrate W due to the formation of the anisotropic structure, and a change in the peak intensities of the TO phonon and LO phonon in the absorbance spectrum is observed. FIG. 12 is a diagram for explaining dependence of the substrate W on the polarization. In FIG. 12, substrates W31 to W33 are shown in first to third rows. The substrate W31 in the first row is the substrate W in which the trench 92 is formed. The substrate W32 in the second row is a substrate W in which a plurality of holes 94 are formed evenly. The substrate W33 in the third row is the flat silicon substrate 95 having the flat film 96 formed on its surface.

In the figure, “Top view” schematically shows upper surfaces of the substrates W31 to W33, and “Side view” schematically shows cross sections of the substrates W31 to W33. “IR spectrum” schematically shows the absorbance spectra of the substrates W31 to W33 when the side view is an incidence plane and the measurement light is P-polarized measurement light (P), S-polarized measurement light (S), and unpolarized measurement light (No). The absorbance spectra were measured by irradiating the measurement light perpendicularly to the substrates W31 to W33.

The substrate W31 shown in the first row has trenches 92 formed side by side therein. Thus, the shape of the pattern does not have in-plane isotropy. As a result, waveforms of the absorbance spectra of the P-polarized measurement light, the S-polarized measurement light, and the unpolarized measurement light on the substrate W31 are different from each other. The substrate W31 has dependence on polarization. The substrate W31 may separate the LO phonon and the TO phonon by a polarization control as described below.

The substrate W32 shown in the second row has holes 94 formed evenly lengthwise and widthwise. The holes 94 are a true circle. Thus, the shape of the pattern has the in-plane isotropy. As a result, the waveforms of the absorbance spectra of the P-polarized measurement light, the S-polarized measurement light, and the unpolarized measurement light on the substrate W32 are similar to each other. Thus, the substrate 32 has not dependence on polarization.

Although the LO phonon and the TO phonon may be observed in the substrate W32, the LO phonon and the TO phonon cannot be separated from each other by polarization alone.

The flat substrate W33 shown in the third row has a flat upper surface. Thus, the flat substrate W33 has the in-plane isotropy. The flat substrate W33 has similar waveforms in the absorbance spectra of the P-polarized measurement light, the S-polarized measurement light, and the unpolarized measurement light. Thus, the flat substrate W33 has no dependence on polarization. Only the TO phonon is observed in the flat substrate W33.

As described with reference to FIGS. 6A and 6B, depending on the polarization of the measurement light, the shape of the absorbance spectrum is changed in the substrate W31 in which the trench 92 is formed. When the polarization of the measurement light is perpendicular to the trench 92 (Perpendicular to trench), the TO phonon and the LO phonon of the film 91 on the surface of the substrate W31 are observed. When the polarization of the measurement light is parallel to the trench 92 (Parallel to trench), the TO phonon of the film 91 on the surface of the substrate W31 is observed.

In the substrate evaluation method according to the second embodiment, a film quality of the film 91 formed on the trench 92 of the substrate W is evaluated as follows.

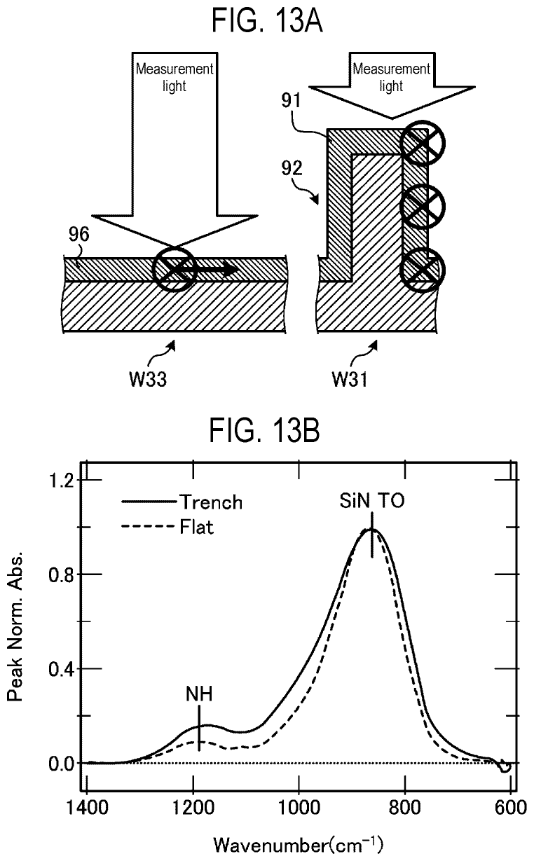

FIGS. 13A and 13B are diagrams for explaining an example of the film quality evaluated by the substrate evaluation method according to the second embodiment. In the substrate evaluation method according to the second embodiment, the film 91 is formed on the substrate W31 in which the trench 92 is formed, and the FT-IR analysis is performed on the substrate W after the film formation to measure the absorbance spectrum. Specifically, the substrate W is transferred to the film forming apparatus 100, and is placed on the stage 2. The film forming apparatus 100 performs a film forming process of forming the film 91 made of the infrared-active material (for example, SiN) on the substrate W31 by the plasma ALD. The film forming apparatus 100 measures the absorbance spectrum of the substrate W31 on which the film forming process has been performed. The film forming apparatus 100 measures the absorbance spectrum of the substrate W with the P-polarized measurement light polarized parallel to the trench 92 (the P-polarized measurement light). By polarizing the measurement light parallel to the trench 92, the TO phonon may be observed in the absorbance spectrum of the substrate W31.

Further, in the substrate evaluation method according to the second embodiment, the film 96 is formed on the flat substrate W33 under the same conditions as those used in the formation of the film 91, and the FT-IR analysis is performed on the flat substrate W33 after the film formation to measure the absorbance spectrum. Specifically, the flat substrate W33 is transferred to the film forming apparatus 100, and is placed on the stage 2. The film forming apparatus 100 performs a film forming process of forming the film 96 made of the infrared-active material (for example, SiN) on the flat substrate W33 under the same conditions as those used in the formation of the film 91. The film forming apparatus 100 performs the FT-IR analysis on the flat substrate W33 after the film forming process to measure the absorbance spectrum. The TO phonon may be observed in the absorbance spectrum of the flat substrate W33.

As described with reference to FIGS. 7A and 7B, the incident angle of the measurement light in the FT-IR analysis may be any angle. For example, the measurement light may be perpendicularly incident on the substrate W31 or W33, and the infrared light transmitted through or reflected by the substrate W31 or W33 may be detected to obtain the absorbance spectrum. Alternatively, the measurement light may be obliquely incident on the substrate W31 or W33, and the infrared light transmitted through or reflected by the substrate W31 or W33 may be detected to obtain the absorbance spectrum.

In the substrate evaluation method according to the second embodiment, the absorbance spectrum of the substrate W31 in which the trench 92 is formed is compared with the absorbance spectrum of the flat substrate W33 to evaluate the film quality of the film 91 formed on the substrate W31.

For example, in the substrate evaluation method according to the second embodiment, the absorbance spectrum of the substrate W31 having the trench 92 formed therein, which is measured by the P-polarized measurement light parallel to the trench 92, is compared with the absorbance spectrum of the flat substrate W33, and the film quality of the film 91 formed in the trench 92 is derived based on the comparison result. Specifically, the controller 60 specifies the peak intensity of the TO phonon of each of the absorbance spectrum of the substrate W31 having the trench 92, which is measured by the P-polarized measurement light polarized parallel to the trench 92, and the absorbance spectrum of the flat substrate W33. The controller 60 normalizes the absorbance spectrum of the substrate W31 having the trench 92, which is measured by the P-polarized measurement light polarized parallel to the trench 92, and the absorbance spectrum of the flat substrate W33, based on the value of the peak intensity of the TO phonon of each of the absorbance spectra. The controller 60 compares the normalized absorbance spectrum based on the P-polarized measurement light in the substrate W31 having the trench 92 with the normalized absorbance spectrum of the flat substrate W33. FIG. 13B shows the normalized absorbance spectrum based on the P-polarized measurement light in the substrate W31 (Trench) having the trench 92 and the normalized absorbance spectrum of the flat substrate W33 (Flat). In FIG. 13B, the substrate W31 (Trench) having the trench 92 has a wider half-width of the TO phonon peak waveform than the flat substrate W33 (Flat). Further, the substrate W31 (Trench) having the trench 92 has a larger NH area intensity than the flat substrate W33 (Flat). From this, it may be estimated that the film 91 formed on the substrate W31 has a larger structural disturbance and contains more impurities than the film 96 formed on the flat substrate W33. As a result, the film 91 has a poor film quality.

The controller 60 evaluates the quality of the film 91 according to an amount of deviation of the normalized absorbance spectrum of the substrate W31 having the trench 92 from the normalized absorbance spectrum of the flat substrate W33 based on the P-polarized measurement light. For example, the controller 60 evaluates the quality of the film 91 under the assumption that the larger the half-width of the peak waveform of the TO phonon or the area intensity of NH is, the worse the film quality is. In this way, the substrate evaluation method according to the second embodiment may detect the quality of the film 91 formed in the trench 92.

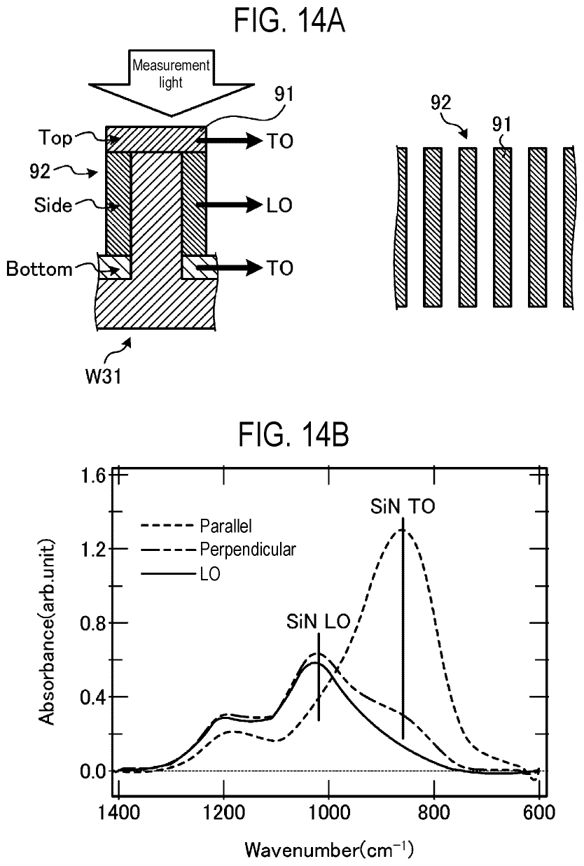

Further, in the substrate evaluation method according to the second embodiment, a TO phonon signal and a LO phonon signal may be separated from each other by performing the polarization control and measuring the absorbance spectrum as follows. FIGS. 14A and 14B are diagrams for explaining the separation of the TO phonon signal and the LO phonon signal from each other according to the second embodiment. In the substrate evaluation method according to the second embodiment, the film 91 is formed on the substrate W31 having the trench 92 formed therein, and the FT-IR analysis is performed on the substrate W31 after the film formation to measure the absorbance spectrum. Specifically, the substrate W31 having the trench 92 formed therein is transferred to the film forming apparatus 100, and the substrate W31 is placed on the stage 2. The film forming apparatus 100 performs a film forming process of forming the film 91 made of the infrared-active material (for example, SiN) on the substrate W31 by the plasma ALD. The film forming apparatus 100 performs the FT-IR analysis on the substrate W31 after the film forming process to measure the absorbance spectrum. The film forming apparatus 100 performs the polarization control to measure the absorbance spectrum of the substrate W31 using the P-polarized measurement light polarized parallel to the trench 92 (parallel polarization).

Further, the film forming apparatus 100 performs the polarization control to measure the absorbance spectrum of the substrate W31 using the S-polarized measurement light polarized perpendicular to the trench 92 (perpendicular polarization). By measuring the absorbance spectrum of the substrate W31 through the parallel polarization in which the measurement light is polarized parallel to the trench 92, the TO phonon is observed. Further, by measuring the absorbance spectrum of the substrate W31 through the perpendicular polarization in which the measurement light is polarized perpendicular to the trench 92, the TO phonon and the LO phonons are observed. FIG. 14A shows a schematic cross section of the substrate W31 in which the trench 92 of a rectangular shape is formed. In the case of the perpendicular polarization, the TO phonon is generated from the film 91 on a top portion (Top) and a bottom portion (Bottom) of the trench 92, and the LO phonon is generated from the film 91 on a side portion (Side) of the trench 92. In a case in which an aspect ratio of the trench 92 is known, a ratio of a signal intensity between the TO phonon and the LO phonon may be calculated. The aspect ratio of the trench 92 may be specified based on design information of a semiconductor to be manufactured on the substrate W31 or by actually observing the substrate W31. In a case in which the film 91 is formed uniformly in the trench 92 with the same film thickness, when the aspect ratio of the trench 92 is specified, a volume ratio between the top portion (Top), the bottom portion (Bottom), and the side portion (Side) of the film 91 formed in the trench 92 is determined. The volume ratio is (Top, Side, Bottom)=(a, b, c).

In the FT-IR analysis using the S-polarized measurement light (the perpendicular polarization), a peak intensity ratio of the TO phonon to the LO phonon is (a+c)/2b.

A parallel polarization signal of the absorbance spectrum of the substrate W31 measured with the P-polarized measurement light includes the TO phonon signal generated from the film 91 in the top portion, the bottom portion, and the side portion of the trench 92. From the volume ratio between the top portion, the bottom portion, and the side portion of the trench 92, the TO phonon signal generated from the film 91 in the top portion and the bottom portion of the trench 92 becomes the parallel polarization signal×(a+c)/2b.

A perpendicular polarization signal of the absorbance spectrum of the substrate W31 measured with the S-polarized measurement light includes the LO phonon signal generated from the film 91 in the top portion and the bottom portion of the trench 92, and the LO phonon signal generated from the film 91 in the side portion of the trench 92. The LO phonon signal may be calculated from Formula (1) below.

$$LO phonon signal = Perpendicular polarization signal - Parallel polarization signal \times ( a + c ) / 2 b \qquad ( 1 )$$

FIG. 14B shows the absorbance spectrum measured using the perpendicular polarization (Perpendicular) and the absorbance spectrum measured using the parallel polarization (Parallel). Further, in FIG. 14B, the absorbance spectrum by the LO phonon signal (LO) obtained in Formula (1) above is shown. By separating the TO phonon signal and the LO phonon signal from each other in this way, the signals of the top portion (Top) and the bottom portion (Bottom) of the trench 92 and the signal of the side portion (Side) may be separated from each other.

By performing the analysis in the same way, the LO phonon signal may be extracted from the signal of the absorbance spectrum obtained using the unpolarized light or the oblique incidence. In addition, although the rectangular trench is used as an example in the above embodiment, the present disclosure may be applied to various trenches with complex patterns such as a trapezoidal shape, a bent shape and the like. In addition, the TO phonon signal and the LO phonon signal may be separated from each other using global fitting or multivariate analysis.

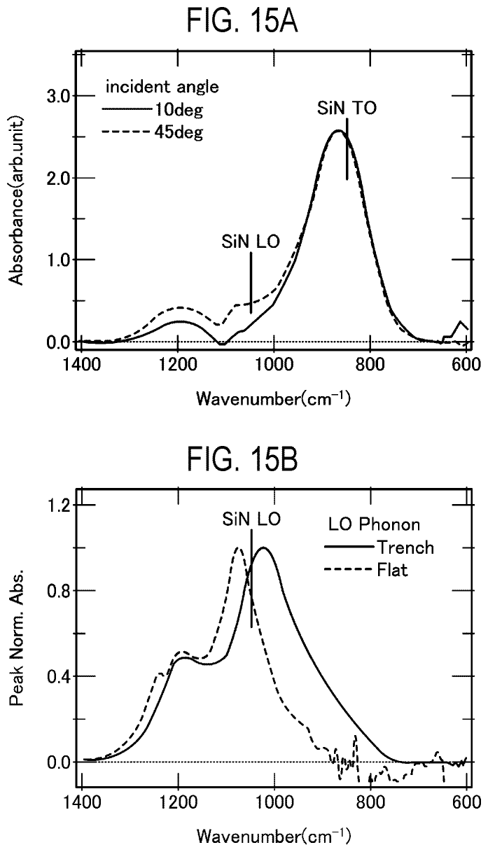

FIGS. 15A and 15B are diagrams for explaining an example of a film quality evaluation by the substrate evaluation method according to the second embodiment. The film forming apparatus 100 derives the evaluation information about the trench 92 from at least one of the TO phonon signal or the LO phonon signal separated from each other by performing the polarization control as described above. For example, the controller 60 compares the separated LO phonon signal of the trench 92 with the LO phonon signal of the flat substrate W33. The LO phonon signal of the flat substrate W33 may be obtained by irradiating the infrared light as the measurement light onto the flat substrate W33 from an oblique direction at different incident angles, measuring intensity spectra, and calculating absorbance spectra at the different incident angles. In FIG. 15A, the absorbance spectrum when the incident angle is 10 degrees (10 deg) and the absorbance spectrum when the incident angle is 45 degrees (45 deg) are shown. For example, a difference between the absorbance spectrum at the incident angle of 45 degrees and the absorbance spectrum at the incident angle of 10 degrees is defined as the LO phonon signal of the flat substrate W33. The film forming apparatus 100 stores data about the LO phonon signal of the flat substrate W33 in the memory 62. The data about the LO phonon signal of the flat substrate W33 may be obtained by performing the FT-IR analysis on the flat substrate W33 in the film forming apparatus 100, or may be obtained by performing the FT-IR analysis on the flat substrate W33 in another apparatus.

The controller 60 compares the absorbance spectrum of the LO phonon of the trench 92 with the absorbance spectrum of the LO phonon of the flat substrate W33, and derives the film quality of the film 91 formed in the trench 92 based on the comparison result. For example, the controller 60 normalizes the absorbance spectrum indicated by the separated LO phonon signal of the trench 92 and the absorbance spectrum indicated by the LO phonon signal of the flat substrate W33 using a value of the peak intensity of the LO phonon of each the absorbance spectra. The controller 60 compares the normalized absorbance spectrum of the LO phonon of the trench 92 with the normalized absorbance spectrum of the LO phonon of the flat substrate W33. In FIG. 15B, the normalized absorbance spectrum of the separated LO phonon of the trench 92 (Trench) and the normalized absorbance spectrum of the LO phonon of the flat substrate W33 (Flat) are shown. The normalized absorbance spectrum of the LO phonon of the trench 92 indicates a state of the film 91 in the side portion of the trench 92.

As shown in FIG. 15B, the absorbance spectrum (Trench) of the LO phonon of the trench 92 has a different peak wavenumber and spectrum width from the absorbance spectrum (Flat) of the LO phonon of the flat substrate W33. This indicates that a composition of the film 91 in the side portion of the trench 92 is different from that of the film 96 on the flat substrate W33.

The controller 60 evaluates the film quality of the film 91 in the side portion of the trench 92 according to an amount of deviation of the absorbance spectrum of the LO phonon of the trench 92 from the absorbance spectrum of the LO phonon of the flat substrate W33. For example, the controller 60 evaluates the film quality of the film 91 in the side portion of the trench 92 under the assumption that the greater the amount of deviation, the worse the film quality. Thus, the substrate evaluation method according to the second embodiment may derive the film quality of the film 91 in the side portion of the trench 92.

In FIG. 15B, the example has been described in which the LO phonon signal of the trench 92 is compared with the LO phonon signal of the flat substrate W33. However, the present disclosure is not limited thereto. By separating the TO phonon signal of the trench 92 and comparing the TO phonon signal of the trench 92 with the LO phonon signal of the flat substrate W33, the film quality of the film 91 in the top portion and the bottom portion of the trench 92 may be evaluated.

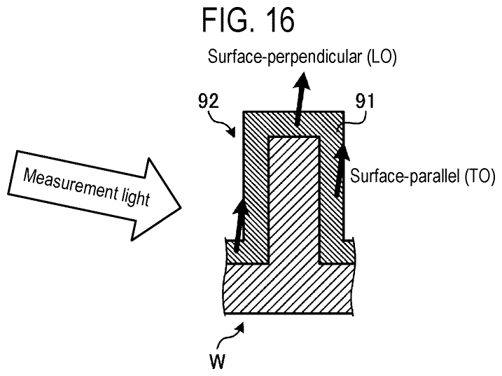

In the FT-IR analysis, the measurement light may be incident from a direction close to the plane of the substrate W. FIG. 16 is a diagram showing an example of the incident angle of the measurement light on the substrate W according to the second embodiment. In FIG. 16, the substrate W on which the trench 92 is formed is shown. In the FT-IR analysis, the measurement light is incident from the direction close to the plane of the substrate W. The measurement light may be incident within an angle of 30 degrees from the plane of the substrate W, more specifically within an angle of 10 degrees from the plane of the substrate W. In the substrate W on which the trench 92 is formed, the measurement light is incident from the direction close to the plane of the substrate W to obtain the LO phonon signal in the top portion and the bottom portion of the trench 92, and the TO phonon signal in the side portion of the trench 92. In FIG. 14B, the LO phonon signal is extracted as a signal from the side portion of the trench 92. Alternatively, by performing calculation in a similar manner, the TO phonon signal may be extracted as a signal from the side portion of the trench 92.

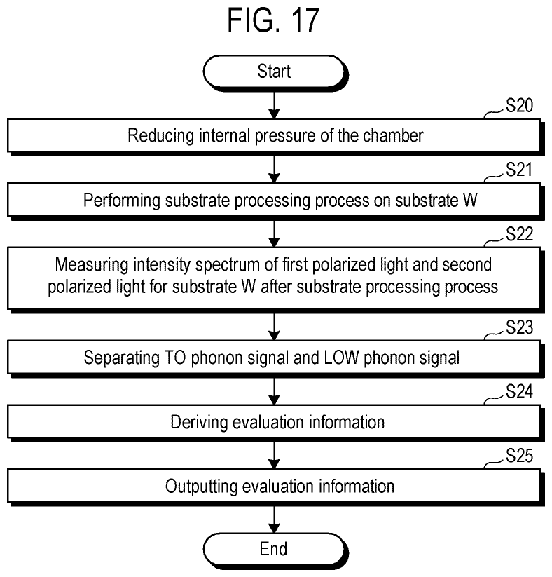

Next, a flow of the substrate processing including the process of the substrate evaluation method according to the second embodiment will be described. FIG. 17 is a flowchart for explaining an example of the flow of the substrate processing according to the second embodiment.

The substrate W having the trench 92 formed therein is placed on the stage 2 by a transfer mechanism such as a transfer arm (not shown). The film forming apparatus 100 reduces the internal pressure of the chamber 1 (Step S20). For example, the controller 60 controls the exhaust device 73 to reduce the internal pressure of the chamber 1.

The film forming apparatus 100 performs the substrate processing on the substrate W (Step S21). For example, the controller 60 controls the gas supply 15 and the radio-frequency power supply 10 to form the film 91 on the surface of the substrate W by the plasma ALD.

Subsequently, the film forming apparatus 100 measures intensity spectra of two different polarized lights in the substrate W after the substrate processing (Step S22). For example, the controller 60 controls the irradiator 81 to individually irradiate the substrate W with two different polarized infrared lights, and detects the transmitted light that has passed through the substrate W or the reflected light that has been reflected by the substrate W with the detector 82. The controller 60 obtains the intensity spectra of the two different polarized lights in the substrate W from data detected by the detector 82.

Subsequently, the film forming apparatus 100 calculates an absorbance spectrum from the intensity spectra of the two different polarized lights in the substrate W and the intensity spectrum before the substrate processing stored in advance. The TO phonon signal and the LO phonon signal are separated from the absorbance spectrum (Step S23). For example, the controller 60 separates the difference spectrum of the two different polarized lights into the TO phonon signal and the LO phonon signal based on the volume ratio (Top, Side, Bottom) of the film 91 formed in the trench 92.

Subsequently, the film forming apparatus 100 derives the evaluation information about the trench 92 from at least one of the TO phonon signal or the LO phonon signal thus separated (Step S24). For example, the controller 60 compares the separated LO phonon signal of the trench 92 with the LO phonon signal of the flat substrate W33, and derives the film quality of the film 91 in the side portion of the trench 92 based on the comparison result.

Subsequently, the film forming apparatus 100 outputs the derived evaluation information about the trench 92 (Step S25), and terminates the process. For example, the controller 60 outputs the film quality of the film 91 derived in the side portion of the trench 92 to the user interface 61. Thus, the process manager may grasp a state of the film 91 in the side portion of the trench 92 in real time. The controller 60 may output the evaluation information about the trench 92 to another apparatus. Further, the controller 60 may output the evaluation information about the trench 92 to the memory 62 or an external memory device.

Therefore, the film forming apparatus 100 may detect the state of the film 91 in the side portions of the trench 92 formed in the substrate W.

In the second embodiment, the example has been described in which the intensity spectra of the two different polarized lights are measured by performing the polarization control on the substrate W31 after the film 91 is formed, and the evaluation information about the trench 92 is derived from the absorbance spectrum calculated from the intensity spectra of the two different polarized lights. However, the present disclosure is not limited thereto. In the second embodiment, the intensity spectra of the substrate W31 before the film 91 is formed and the substrate W31 after the film 91 is formed may be measured as in the first embodiment. In the second embodiment, the absorbance spectrum may be calculated from the intensity spectrum of the substrate W before the film is formed and the intensity spectrum of the substrate W after the film is formed, and the evaluation information about the trench 92 may be derived. For example, the film forming apparatus 100 performs the polarization control on the substrate W31 before the film 91 is formed and the substrate W31 after the film is formed, and measures the absorbance spectra of the two different polarized lights. The controller 60 calculates the absorbance spectrum from the intensity spectrum of the substrate W before the film is formed and the intensity spectrum of the substrate W after the film is formed, using the perpendicular polarization and the parallel polarization, respectively. The controller 60 separates the absorbance spectra of the two different polarized lights into the TO phonon signal and the LO phonon signal from each other based on the volume ratio (Top, Side, Bottom) of the film 91 formed in the trench 92. The controller 60 compares the absorbance spectrum of at least one of the TO phonon signal or the LO phonon signal thus separated with the absorbance spectrum of at least one of the LO phonon or the TO phonon of the flat substrate W33, to derive the evaluation information about the trench 92.

As described above, the substrate evaluation method according to the second embodiment includes the measurement operation (Step S22) and the derivation operation (Step S23). In the measurement operation, the substrate W (the substrate W31) on which the anisotropic structure is formed is analyzed by the infrared spectroscopy to measure the absorbance spectrum in the wavenumber range including a peak of at least one of the LO phonon or the TO phonon. In the derivation operation, the evaluation information about the anisotropic structure is derived from the measured absorbance spectrum. Thus, the substrate evaluation method according to the second embodiment may detect a state of the anisotropic structure formed on the substrate W.

Further, the structure is the trench 92 formed in the substrate W. In the measurement operation, the substrate W (the substrate W31) is irradiated with the infrared light polarized parallel to the trench 92 to measure the intensity spectrum. In the derivation operation, the measured absorbance spectrum obtained using the parallel polarization is compared with the absorbance spectrum obtained by performing the infrared spectroscopy analysis on the flat substrate W33 to derive the evaluation information about the trench 92. Thus, the substrate evaluation method according to the second embodiment may derive evaluation information about the film quality of the trench 92.

Further, the structure is the trench 92 formed in the substrate W. The measurement operation includes the first polarized-light measurement operation and the second polarized-light measurement operation. In these two measurement operations, intensity spectra are measured using two different polarized lights. For example, the first polarized-light measurement operation measures an absorbance spectrum by irradiating the substrate W (the substrate W31) with infrared light polarized parallel to the trench 92, which is a first polarized light. The second polarized-light measurement operation measures an absorbance spectrum by irradiating the substrate W (the substrate W31) with infrared light perpendicular to the first polarized light, which is a second polarized light. The derivation operation derives an absorbance spectrum by at least one of the LO phonon or the TO phonon from the absorbance spectrum measured in the first polarized-light measurement operation, the absorbance spectrum measured in the second polarized-light measurement operation, and the aspect ratio of the trench 92. Thus, the substrate evaluation method according to the second embodiment may separate the absorbance spectra of the LO phonon and the TO phonon from each other.

Further, the derivation operation compares the derived absorbance spectrum by at least one of the LO phonon or the TO phonon with the absorbance spectrum by at least one of the LO phonon or the TO phonon obtained by performing the infrared spectroscopy analysis on the flat substrate W33 to derive the evaluation information about the trench 92. Thus, the substrate evaluation method according to the second embodiment may derive evaluation information about film qualities of the top portion, the bottom portion, and the side portion of the trench 92.

Although the embodiments have been described above, the disclosed embodiments should be considered to be exemplary and not limitative in all respects. Indeed, the above-described embodiments may be embodied in various forms. Further, the above-described embodiments may be omitted, substituted, or modified in various forms without departing from the scope and spirit of the claims.

For example, in the above-described embodiments, the irradiator 81 is configured to be movable vertically and rotatable, and the incident angle of the infrared light incident on the substrate W is changeable. However, the present disclosure is not limited thereto. For example, optical elements such as mirrors and lenses may be provided in the optical path of the infrared light irradiated from the irradiator 81 or the optical path of the infrared light incident on the detector 82, and the incident angle of the infrared light incident on the substrate W may be changed by the optical elements.

In the above-described embodiment, the state of the trench 92 near the center of the substrate W is detected by transmitting or reflecting the infrared light near the center of the substrate W. However, the present disclosure is not limited thereto. For example, optical elements such as mirrors and lenses that reflect the infrared light may be provided in the chamber 1, the optical elements may irradiate the infrared light to a plurality of locations, such as near the center and near the periphery of the substrate W, and transmitted light or reflected light may be detected at each location to detect the state of the trench 92 of the substrate W that has been subjected to the substrate processing at each of the plurality of locations on the substrate W.

Further, in the above-described embodiment, the example has been described in which the substrate processing apparatus according to the present disclosure is a single-chamber type film forming apparatus 100 equipped with a single chamber. However, the present disclosure is not limited thereto. The substrate processing apparatus according to the present disclosure may be a multi-chamber type film forming apparatus equipped with a plurality of chambers.

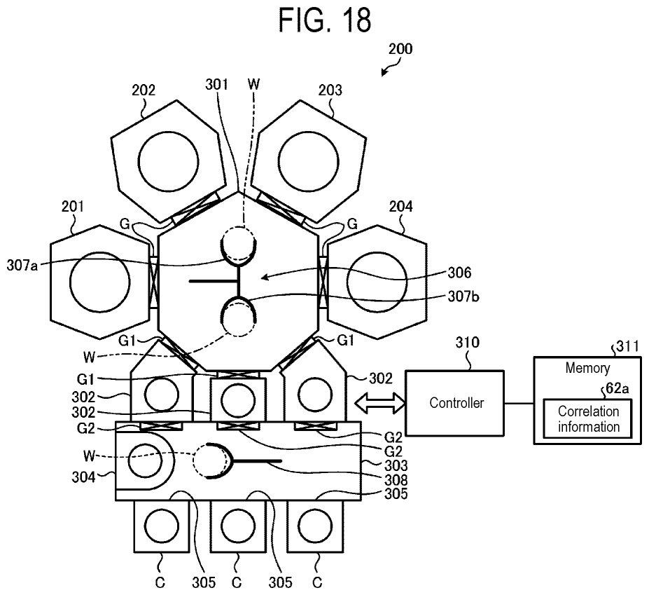

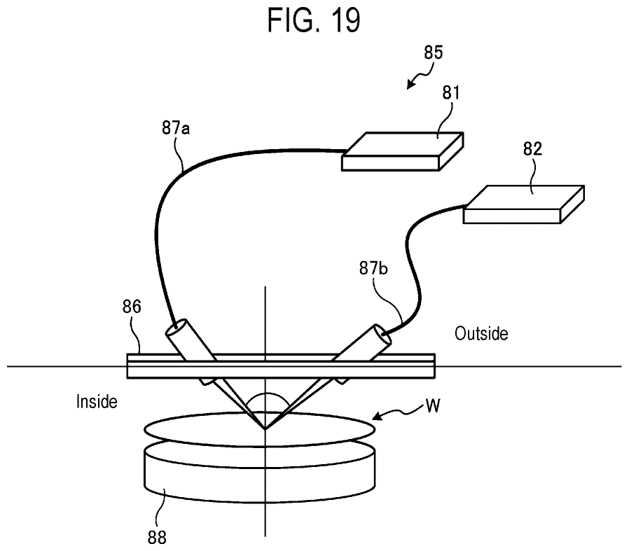

FIG. 18 is a schematic diagram showing a film forming apparatus 200 according to another embodiment. As shown in FIG. 18, the film forming apparatus 200 is a multi-chamber type film forming apparatus equipped with four chambers 201 to 204. In the film forming apparatus 200, the plasma ALD is performed in each of the four chambers 201 to 204.

The chambers 201 to 204 are connected to four walls of a vacuum transfer chamber 301, which has a heptagonal planar shape, via gate valves G. An interior of the vacuum transfer chamber 301 is exhausted by a vacuum pump and kept at a predetermined level of vacuum.

Three load lock chambers 302 are connected to the other three walls of the vacuum transfer chamber 301 via gate valves G1. An atmospheric transfer chamber 303 is provided on a side of the load lock chambers 302 opposite the vacuum transfer chamber 301. The three load lock chambers 302 are connected to the atmospheric transfer chamber 303 via gate valves G2. The load lock chambers 302 control the pressure between the atmospheric pressure and the vacuum when transferring the substrate W between the atmospheric transfer chamber 303 and the vacuum transfer chamber 301.

Three carrier attachment ports 305 for attaching carriers (FOUPs or the like) C configured to accommodate substrates W are provided on a wall of the atmospheric transfer chamber 303 opposite the wall to which the load lock chamber 302 is attached. In addition, an alignment chamber 304 configured to align the substrates W is provided on the sidewall of the atmospheric transfer chamber 303. A down-flow of clean air is formed in the atmospheric transfer chamber 303.

A transfer mechanism 306 is provided inside the vacuum transfer chamber 301. The transfer mechanism 306 transfers the substrate W to and from the chambers 201 to 204 and the load lock chambers 302. The transfer mechanism 306 includes two transfer arms 307a and 307b configured to be movable independently of each other.

A transfer mechanism 308 is provided inside the atmospheric transfer chamber 303. The transfer mechanism 308 transfers the substrate W between the carrier C, the load lock chambers 302, and the alignment chamber 304.

The film forming apparatus 200 includes a controller 310. An overall operation of the film forming apparatus 200 is controlled by the controller 310. A memory 311 is connected to the controller 310.

The memory 311 stores programs (software) for implementing various processes executed in the film forming apparatus 200 under the control of the controller 310, and data such as process conditions and process parameters. For example, the memory 311 stores the correlation information 62a.

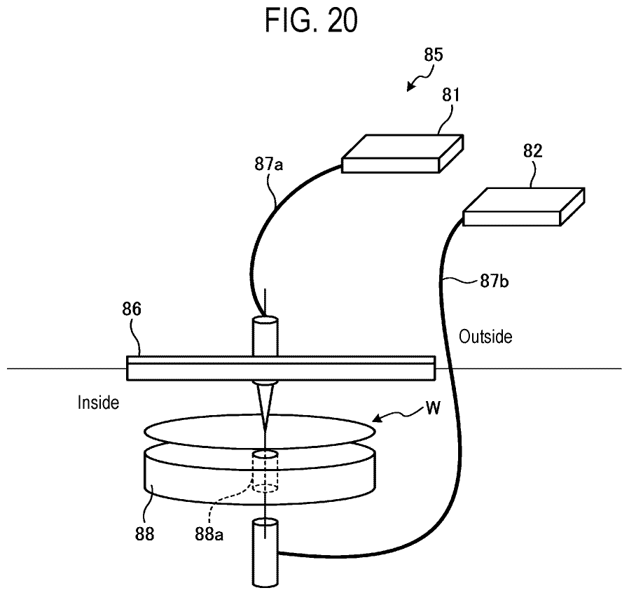

In the film forming apparatus 200 configured as above, the measurer 85 configured to measure the substrate W by the infrared spectroscopy may be provided in any one of the chambers 201 to 204. For example, in the film forming apparatus 200, the measurer 85 configured to measure the substrate W by the infrared spectroscopy is provided in any one of the vacuum transfer chamber 301, the load lock chambers 302, the atmospheric transfer chamber 303, and the alignment chamber 304. FIGS. 19 and 20 are diagrams showing an example of a schematic configuration of the measurer 85 according to an embodiment. FIG. 19 shows a case in which the measurer 85 is configured to be capable of performing the infrared spectroscopy analysis based on the reflection method. FIG. 20 shows a case in which the measurer 85 is configured to be capable of performing the infrared spectroscopy analysis based on the transmission method. The measurer 85 includes the irradiator 81 configured to irradiate light and the detector 82 configured to detect the light. The irradiator 81 and the detector 82 are arranged outside a housing 86 such as the vacuum transfer chamber 301, the load lock chamber 302, the atmospheric transfer chamber 303, the alignment chamber 304, or the like. Light guiding members 87a and 87b such as optical fibers are connected to the irradiator 81 and the detector 82. End portions of the light guiding members 87a and 87b are disposed in the housing 86. The infrared light outputted from the irradiator 81 is outputted from the end portion of the light guiding member 87a. In FIG. 19, the end portion of the light guiding member 87a is disposed so that the infrared light is incident on the substrate W at a predetermined incident angle (for example, 45 degrees). The end portion of the light guiding member 87a is disposed so that the infrared light reflected from the substrate W is incident on the end portion of the light guiding member 87a. In FIG. 20, the end portion of the light guiding member 87a is disposed so that the infrared light is perpendicularly incident on the substrate W. A through-hole 88a is formed in a stage 88 on which the substrate W is placed, at a position on the infrared light is incident. The end portion of the light guiding member 87a is disposed above the through-hole 88a. In FIG. 20, the infrared light incident on the substrate W passes through the through-hole 88a and is incident on the end portion of the light guiding member 87b. The infrared light incident on the end portion of the light guiding member 87b is detected by the detector 82 via the light guiding member 87b. The measurer 85 performs spectroscopic measurement on the substrate W. The controller 310 measures the absorbance spectrum of the substrate W from the infrared light received by the detector 82. The controller 310 derives evaluation information about the anisotropic structure formed on the substrate W that has been subjected to the substrate processing from the measured absorbance spectrum based on the correlation information 62a. For example, the controller 310 derives the evaluation information about the trench 92 formed in the substrate W. Therefore, the film forming apparatus 200 may detect the state of the anisotropic structure formed on the substrate W.

In the above example, the substrate processing apparatus of the present disclosure has been described as a single-chamber type substrate processing apparatus or a multi-chamber type substrate processing apparatus equipped with a plurality of chambers. However, the present disclosure is not limited thereto. For example, the substrate processing apparatus of the present disclosure may be a batch type substrate processing apparatus capable of processing a plurality of substrates at once, or a carousel type semi-batch type substrate processing apparatus.

According to the present disclosure in some embodiments, it is possible to detect a state of an anisotropic structure formed on a substrate.

The disclosed embodiments should be considered to be exemplary and not limitative in all respects. Indeed, the above-described embodiments may be embodied in various forms. Further, the above-described embodiments may be omitted, substituted, or modified in various forms without departing from the scope and spirit of the appended claims.

Hereinafter, Supplementary Notes are provided for the above-described embodiments.

### (Supplementary Note 1)

A substrate evaluation method includes: a measurement operation of measuring an absorbance spectrum in a wavenumber range including a peak of at least one of a LO (Longitudinal Optical) phonon or a TO (Transverse Optical) phonon by analyzing a substrate having an anisotropic structure formed thereon with an infrared spectroscopy analysis; and a derivation operation of deriving evaluation information about the anisotropic structure from the measured absorbance spectrum.

### (Supplementary Note 2)

In the substrate evaluation method of Supplementary Note 1 above, the anisotropic structure is a trench formed in the substrate.

### (Supplementary Note 3)

In the substrate evaluation method of Supplementary Note 2 above, the trench is formed with a film made of an infrared-active material, and the derivation operation determines peak intensities of the LO phonon and the TO phonon made of the infrared-active material from the absorbance spectrum, and derives an opening width of the trench as the evaluation information from the peak intensities of the LO phonon and the TO phonon.

### (Supplementary Note 4)

In the substrate evaluation method of Supplementary Note 3 above, the infrared-active material is a material containing Si atoms and N atoms.

### (Supplementary Note 5)

The substrate evaluation method of any one of Supplementary Notes 1 to 4 above further includes a substrate processing operation of performing substrate processing on the substrate,
the measurement operation includes:
a pre-substrate-processing measurement operation of performing the infrared spectroscopy analysis on the substrate, which has not been subjected to the substrate processing in the substrate processing operation, to measure an intensity spectrum before the substrate processing; and
a post-substrate-processing measurement operation of performing the infrared spectroscopy analysis on the substrate, which has been subjected to the substrate processing in the substrate processing operation, to measure an intensity spectrum after the substrate processing, and
the derivation operation derives the evaluation information about the anisotropic structure from the intensity spectrum before the substrate processing measured in the pre-substrate-processing measurement operation and the intensity spectrum after the substrate processing measured in the post-substrate-processing measurement operation.

### (Supplementary Note 6)

In the substrate evaluation method of Supplementary Note 5 above, the substrate processing operation performs the substrate processing including forming a film made of an infrared-active material on the substrate, or exposing the infrared-active material contained in the substrate, and
the derivation operation calculates the absorbance spectrum from the intensity spectrum before the substrate processing and the intensity spectrum after the substrate processing, obtains a peak intensity of the at least one of the LO phonon or the TO phonon made of the infrared-active material from the absorbance spectrum, and derives the evaluation information about the anisotropic structure from the peak intensity of the at least one of the LO phonon or the TO phonon.

### (Supplementary Note 7)

In the substrate evaluation method of any one of Supplementary Notes 1 to 6 above, the anisotropic structure is a trench formed in the substrate,
the measurement operation irradiates the trench of the substrate with parallel polarization infrared light to measure the absorbance spectrum, and
the derivation operation compares the absorbance spectrum measured by the parallel polarization infrared light with an absorbance spectrum obtained by analyzing the substrate of a flat shape with the infrared spectroscopy analysis to derive evaluation information about the trench.

### (Supplementary Note 8)

In the substrate evaluation method of any one of Supplementary Notes 1 to 6 above, the anisotropic structure is a trench formed in the substrate,
the measurement operation includes a first polarized-light measurement operation of irradiating the trench of the substrate with a first polarized infrared light to measure a first absorbance spectrum, and a second polarized-light measurement operation of irradiating the trench of the substrate with a second polarized infrared light different from the first polarized infrared light to measure a second absorbance spectrum, and
the derivation operation derives the absorbance spectrum of the at least one of the LO phonon or the TO phonon from the first absorbance spectrum measured with the first polarized infrared light in the first polarized-light measurement operation, the second absorbance spectrum measured with the second polarized infrared light in the second polarized-light measurement operation, and an aspect ratio of the trench.

### (Supplementary Note 9)

In the substrate evaluation method of Supplementary Note 8 above, the first polarized infrared light and the second polarized infrared light are orthogonal to each other.

### (Supplementary Note 10)

In the substrate evaluation method of Supplementary Note 8 above, the first polarized infrared light or the second polarized infrared light is parallel to the trench.

### (Supplementary Note 11)

In the substrate evaluation method of Supplementary Note 8 above, the derivation operation compares at least one of the first absorbance spectrum or the second absorbance spectrum with the absorbance spectrum of the at least one of the LO phonon or the TO phonon, which is obtained by analyzing the substrate of a flat shape with the infrared spectroscopy analysis, to derive evaluation information about the trench.

### (Supplementary Note 12)

In the substrate evaluation method of any one of Supplementary Notes 1 to 11 above, the measurement operation analyzes the substrate with the infrared spectroscopy analysis by perpendicularly irradiating the substrate with infrared light.

### (Supplementary Note 13)

In the substrate evaluation method of any one of Supplementary Notes 1 to 11 above, the measurement operation analyzes the substrate with the infrared spectroscopy analysis by irradiating the substrate with infrared light in a direction close to a plane of the substrate.

### (Supplementary Note 14)

A substrate processing apparatus includes: a measurer configured to measure an absorbance spectrum in a wavenumber range including a peak of at least one of a LO (Longitudinal Optical) phonon or a TO (Transverse Optical) phonon by analyzing a substrate having an anisotropic structure formed thereon with an infrared spectroscopy analysis; and a deriver configured to derive evaluation information about the anisotropic structure from the absorbance spectrum measured by the measurer.

What is claimed is:

1. A substrate evaluation method, comprising:
a measurement operation of measuring an absorbance spectrum in a wavenumber range including a peak of at least one of a LO (Longitudinal Optical) phonon or a TO (Transverse Optical) phonon by analyzing a substrate having an anisotropic structure formed thereon with an infrared spectroscopy analysis; and
a derivation operation of deriving evaluation information about the anisotropic structure from the measured absorbance spectrum.

2. The substrate evaluation method of claim 1, wherein the anisotropic structure is a trench formed in the substrate.

3. The substrate evaluation method of claim 2, wherein the trench is formed with a film made of an infrared-active material, and
wherein the derivation operation determines peak intensities of the LO phonon and the TO phonon made of the infrared-active material from the absorbance spectrum, and derives an opening width of the trench as the evaluation information from the peak intensities of the LO phonon and the TO phonon.

4. The substrate evaluation method of claim 3, wherein the infrared-active material is a material containing Si atoms and N atoms.

5. The substrate evaluation method of claim 1, further comprising:
a substrate processing operation of performing substrate processing on the substrate, wherein the measurement operation includes:
a pre-substrate-processing measurement operation of performing the infrared spectroscopy analysis on the substrate, which has not been subjected to the substrate processing in the substrate processing operation, to measure an intensity spectrum before the substrate processing; and
a post-substrate-processing measurement operation of performing the infrared spectroscopy analysis on the substrate, which has been subjected to the substrate processing in the substrate processing operation, to measure an intensity spectrum after the substrate processing, and
wherein the derivation operation derives the evaluation information about the anisotropic structure from the intensity spectrum before the substrate processing measured in the pre-substrate-processing measurement operation and the intensity spectrum after the substrate processing measured in the post-substrate-processing measurement operation.

6. The substrate evaluation method of claim 5, wherein the substrate processing operation performs the substrate processing including forming a film made of an infrared-active material on the substrate, or exposing the infrared-active material contained in the substrate, and
wherein the derivation operation calculates the absorbance spectrum from the intensity spectrum before the substrate processing and the intensity spectrum after the substrate processing, obtains a peak intensity of the at least one of the LO phonon or the TO phonon made of the infrared-active material from the absorbance spectrum, and derives the evaluation information about the anisotropic structure from the peak intensity of the at least one of the LO phonon or the TO phonon.

7. The substrate evaluation method of claim 1, wherein the anisotropic structure is a trench formed in the substrate,
wherein the measurement operation irradiates the trench of the substrate with parallel polarization infrared light to measure the absorbance spectrum, and
wherein the derivation operation compares the absorbance spectrum measured by the parallel polarization infrared light with an absorbance spectrum obtained by analyzing the substrate of a flat shape with the infrared spectroscopy analysis to derive evaluation information about the trench.

8. The substrate evaluation method of claim 1, wherein the anisotropic structure is a trench formed in the substrate,
wherein the measurement operation includes a first polarized-light measurement operation of irradiating the trench of the substrate with a first polarized infrared light to measure a first absorbance spectrum, and a second polarized-light measurement operation of irradiating the trench of the substrate with a second polarized infrared light different from the first polarized infrared light to measure a second absorbance spectrum, and
wherein the derivation operation derives the absorbance spectrum of the at least one of the LO phonon or the TO phonon from the first absorbance spectrum measured with the first polarized infrared light in the first polarized-light measurement operation, the second absorbance spectrum measured with the second polarized infrared light in the second polarized-light measurement operation, and an aspect ratio of the trench.

9. The substrate evaluation method of claim 8, wherein the first polarized infrared light and the second polarized infrared light are orthogonal to each other.

10. The substrate evaluation method of claim 8, wherein the first polarized infrared light or the second polarized infrared light is parallel to the trench.

11. The substrate evaluation method of claim 8, wherein the derivation operation compares at least one of the first absorbance spectrum or the second absorbance spectrum with the absorbance spectrum of the at least one of the LO phonon or the TO phonon, which is obtained by analyzing the substrate of a flat shape with the infrared spectroscopy analysis, to derive evaluation information about the trench.

12. The substrate evaluation method of claim 1, wherein the measurement operation analyzes the substrate with the infrared spectroscopy analysis by perpendicularly irradiating the substrate with infrared light.

13. The substrate evaluation method of claim 1, wherein the measurement operation analyzes the substrate with the infrared spectroscopy analysis by irradiating the substrate with infrared light in a direction close to a plane of the substrate.

14. A substrate processing apparatus, comprising:
a measurer configured to measure an absorbance spectrum in a wavenumber range including a peak of at least one of a LO (Longitudinal Optical) phonon or a TO (Transverse Optical) phonon by analyzing a substrate having an anisotropic structure formed thereon with an infrared spectroscopy analysis; and
a deriver configured to derive evaluation information about the anisotropic structure from the absorbance spectrum measured by the measurer.
